(19) United States
(12) Patent Application Publication
(10) Pub. No.: US 2023/0220172 A1
(43) Pub. Date: Jul. 13, 2023

(54) MULTILAYER OPTICAL FILMS COMPRISING AT LEAST ONE FLUORINATED (CO)POLYMER LAYER MADE USING A FLUORINATED COUPLING AGENT, AND METHODS OF MAKING AND USING THE SAME

(71) Applicant: 3M INNOVATIVE PROPERTIES COMPANY, St. Paul, MN (US)

(72) Inventors: Brandon R. Pietz, St. Paul, MN (US); Christopher S. Lyons, St. Paul, MN (US); Thomas P. Klun, Lakeland, MN (US); Paul J. Homnick, Lake Elmo, MN (US); Jonathan M. Ryss, St. Paul, MN (US); Tarris A. Sveback, New Richmond, WI (US); Caleb T. Nelson, McKinney, TX (US)

(21) Appl. No.: 17/997,740

(22) PCT Filed: Apr. 28, 2021
(86) PCT No.: PCT/IB2021/053542

§ 371 Date: Nov. 2, 2022

Related U.S. Application Data
(60) Provisional application No. 63/025,178, filed on May 15, 2020.

(51) Int. Cl. C08J 7/04; C08K 5/5313; C23C 14/08; G02B 5/28

(52) U.S. Cl. CPC C08J 7/0423; C08K 5/5313; C23C 14/081; G02B 5/287; C08J 2333/14; C08J 2367/02

(57) ABSTRACT

Multilayer optical films including a substrate and at least a first layer overlaying a surface of the substrate, in which the at least first layer includes a (co)polymer obtained by polymerizing a polymerizable composition including a fluorinated coupling agent and at least one free-radically polymerizable monomer, oligomer, or mixture thereof. Processes for making multilayer optical films using the polymerizable compositions also are taught. Articles including the multilayer optical film also are disclosed, in which the article preferably is selected from a photovoltaic device, a display device, a solid-state lighting device, a sensor, a medical or biological diagnostic device, an electrochromic device, light control device, or a combination thereof.

### TECHNICAL FIELD

The present disclosure relates to polymerizable compositions including fluorinated coupling agents and methods of using fluorinated coupling agents to form fluorinated (co)polymer layers in multilayer optical films.

### BACKGROUND

Crosslinked (co)polymeric layers have been used in thin films for electrical, packaging and decorative applications. These layers can provide desired properties such as desired optical properties, mechanical strength, thermal resistance, chemical resistance, abrasion resistance, transparency, refractive index, and clarity. Multilayer optical films incorporating crosslinked (co)polymeric layers also are known.

Such multilayer optical films can be prepared using a variety of production methods. These methods include liquid coating techniques such as solution coating, roll coating, dip coating, spray coating, spin coating; and dry coating techniques such as Monomer Evaporation and Cure, Chemical Vapor Deposition (CVD), Plasma Enhanced Chemical Vapor Deposition (PECVD), initiated Chemical Vapor Deposition (iCVD), Plasma Polymerization, and Molecular Layer Deposition (MLD). One approach for producing multilayer optical films has been to produce inorganic optical layers, such as aluminum oxide, silicon oxide, titanium oxide or silicon nitride interspersed with (co)polymeric optical layers. The inorganic layers can be deposited using a variety of methods including CVD, PECVD, Atomic Layer Deposition (ALD), sputtering and vacuum processes for thermal or electron beam evaporation of solid materials.

Examples of such multilayer optical films and processes for forming such films can be found, for example, in U.S. Pat. Nos.. 5,877,895 (Shaw, et al.); 6,815,043 (Fleming, et al.); 6,838,183 (Yializis); 6,929,864 (Fleming, et al.); 7,215,473 (Fleming); US20160306084 (Padiyath, et al.) These multilayer optical films have a number of applications in the display, optics, lighting, chemical sensor, biological sensor/diagnostic, and solar markets.

### SUMMARY

The optical performance of a multilayer optical film depends on the difference in refractive index between layers. It is often desirable to maximize this difference by using two materials of significantly different refractive index – a low refractive index material and a high refractive index material. Prior art multilayer optical films often use inorganic MgF₂ as the low refractive index layer (n= 1.38 at 550 nm) or use polymeric coatings with index around 1.5 as low refractive index layers. This disclosure describes the use of low refractive index fluorinated (co)polymer layers with fluorinated coupling agents to realize polymer low refractive index layers with refractive index less than 1.4, optionally wherein the refractive index is from 1.3 to 1.4.

It also can be challenging to bond low surface energy, highly fluorinated (co)polymer layers to high surface energy surfaces like inorganic oxides (e.g., silica) in a way that creates a mechanically-robust film that does not delaminate upon processing or handling. The fluorinated coupling agent needs to have reactive groups that are compatible with the curing chemistry used to deposit the highly fluorinated (co)polymer layer(s). While there are many wetting or compatibilizing agents known to improve formation and bonding of fluorinated (co)polymer layers on inorganic layers (e.g., inorganic layers such as silica), these agents generally are not known to impart fluoromaterial compatibility, for example, good adhesion of the highly fluorinated (co)polymer layer to the inorganic surface.

This disclosure describes the use of fluorinated coupling agents and optional fluorinated photoinitiators to produce fluorinated (co)polymers useful in multilayer optical film applications. These fluorinated coupling agents are generally (1) soluble in and compatible with fluorinated monomers, oligomers, and polymers, (2) able to rapidly chemically bond to an inorganic surface (e.g., silica), (3) also able to rapidly chemically bond to radical-polymerizable fluorinated monomers, oligomers, and (co)polymers (e.g., hexafluoro propylene oxide (HFPO)-diacrylate monomers, oligomers and (co)polymers) and (4) not known to cause a substantial increase in the low refractive index of the formed fluorinated (co)polymer layers. The combination of these properties makes these fluorinated coupling agents useful for creating robust, chemically-bonded, fluorinated (co)polymer layers or films on surfaces where fluorinated materials are typically incompatible (e.g., inorganic layers such as silica).

Thus, in one aspect, the disclosure describes a multilayer optical film comprising a substrate and at least a first optical layer overlaying a surface of the substrate, wherein the first optical layer comprises a (co)polymer obtained by polymerizing a polymerizable composition including at least one free-radically polymerizable monomer, oligomer, or mixture thereof and at least one of the foregoing fluorinated coupling agents and optionally at least one fluorinated photoinitiator.

The fluorinated coupling agents have one of the following formulas:

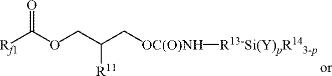

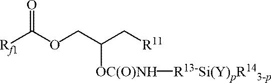

wherein:
R_{f1} is a monovalent perfluorooxyalkyl;
R¹³ is a divalent alkylene group, said alkylene groups optionally containing one or more catenary oxygen atoms;
R¹¹ is -[OC(O)-NH-R¹³]ₘ₁OC(O)CR¹⁵=CH₂ or —OC(O)—NH—R¹⁶(—OC(O)CR¹⁵═CH₂)₂; Y is a hydrolysable group;
R¹⁴ is a monovalent alkyl or aryl group;
p is 1, 2, or 3;
R¹⁵ is H or CH₃;
R¹⁶ is a polyvalent alkylene group, said polyvalent alkylene group optionally containing one or more catenary oxygen atoms; and
m1 is 1 or 0;
or

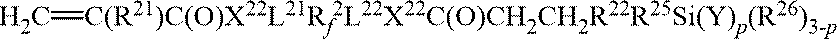

wherein:
R²¹ is H or CH₃;
X²² is -O-,-S-, or -NR²³- wherein R²³ is H or an alkyl group of 1 to 4 carbon atoms,
L²¹ and L²² are organic linking groups;
R_{f}² is a divalent perfluorooxyalkylene;
R²² is -S- or -N(R²⁴)- wherein R²⁴ is C₁-C₄ alkyl or -R²⁵Si(Y)₃;
R²⁵ is a divalent alkylene group optionally comprising one or more catenary oxygen atoms;
Y is a hydrolysable group;
R²⁶ is a non-hydrolysable group; and
p is 1, 2, or 3;
or

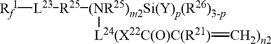

wherein:
R_{f}¹ is a monovalent perfluorooxyalkyl;
L²³ and L²⁴ are organic linking groups;
R²⁵ is a divalent alkylene group said alkylene groups optionally containing one or more catenary oxygen atoms;
Y is a hydrolysable group;
R²⁶ is a non-hydrolysable group;
p is 1, 2, or 3;
X²² is -O-, -S-, or -NR²³-, wherein R²³ is H or an alkyl group of 1 to 4 carbon atoms;
R²¹ is H or CH₃;
m2 is 1 or 2; and
n2 is 1, 2, or 3.

The fluorinated coupling agents are generally used effectively in a polymerizable composition comprising a mixture of at least one of the foregoing fluorinated coupling agents, and at least one free-radically polymerizable monomer, oligomer, or mixture thereof.

In a further aspect, the disclosure describes an article comprising a multilayer optical film according to the foregoing embodiments, wherein the article is selected from a photovoltaic device, a display device, a solid-state lighting device, a sensor, a medical or biological diagnostic device, an electrochromic device, light control device, or a combination thereof.

In still another aspect, the disclosure describes a process for making a multilayer optical film according to the foregoing embodiments, the process comprising forming at least one (co)polymer layer overlaying a substrate, wherein the (co)polymer layer comprises the reaction product of the foregoing polymerizable compositions, and applying at least one adhesion-promoting layer overlaying the substrate, optionally wherein the adhesion-promoting layer comprises an inorganic oxide, nitride, oxynitride, oxycarbide, hydroxylated (co)polymer, or a combination thereof.

Exemplary embodiments of the present disclosure provide multilayer optical films which exhibit optical properties. Exemplary embodiments of the disclosure can enable the formation of multilayer optical films that exhibit superior mechanical properties such as elasticity and flexibility yet still have low oxygen or water vapor transmission rates. Exemplary embodiments of multilayer optical films according to the present disclosure are preferably transmissive to both visible and infrared light. Exemplary embodiments of multilayer optical films according to the present disclosure are also typically flexible. Exemplary embodiments of multilayer optical films according to the present disclosure generally do not exhibit delamination or curl that can arise from thermal stresses or shrinkage in a multilayer structure.

In some exemplary embodiments, the properties of exemplary embodiments of multilayer optical films disclosed herein may be maintained even after high temperature and humidity aging.

Exemplary embodiments of the present disclosure provide multilayer optical films which exhibit improved flexibility and optical performance and low residual stress. Exemplary embodiments of multilayer optical films according to the present disclosure generally do not exhibit delamination, or curl, or crazing that can arise from thermal stresses or deposition stresses in a multilayer optical all-inorganic structure.

Exemplary embodiments of multilayer optical films according to the present disclosure are preferably optically responsive to ultraviolet (UV), visible (VIS) and/or infrared light.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The accompanying drawings are incorporated in and constitute a part of this specification and, together with the description, explain the advantages and principles of exemplary embodiments of the present disclosure.

FIG. 1 is a diagram illustrating an exemplary multilayer optical film incorporating a (co)polymer layer formed using a fluorinated coupling agent according to an exemplary embodiment of the present disclosure; and

FIG. 2 is a diagram illustrating an exemplary process for making a multilayer optical film including at least one layer formed using a fluorinated coupling agent according to an exemplary embodiment of the present disclosure.

Like reference numerals in the drawings indicate like elements. The drawings herein are not drawn to scale, and in the drawings, the illustrated elements are sized to emphasize selected features.

### DETAILED DESCRIPTION

### Glossary

Certain terms are used throughout the description and the claims that, while for the most part are well known, may require some explanation. It should understood that, as used herein,

By using the terms “overcoated,” “overlay” and “overlaying” to describe the position of a layer with respect to a substrate or other layer of a multilayer film of the present disclosure, we refer to the layer as being atop the substrate or other layer, but not necessarily adjoining or contiguous with the substrate or layer.

By using the term “separated by” to describe the position of a layer with respect to one or more other layers, we refer to the other layers as being between the layer and the substrate or another different layer, but not necessarily but not necessarily adjoining or contiguous with the substrate or different layer.

The terms “(co)polymer” and “polymer” include homopolymers and copolymers, such as homopolymers or copolymers that may be formed in a miscible blend, e.g., by coextrusion or by reaction, including, e.g., transesterification. The term “copolymer” includes both random and block copolymers.

The term “coupling agent” means a compound which provides a chemical bond between two dissimilar materials, usually an inorganic and an organic material. Coupling agents are typically multi-functional molecules or oligomers which can act to effect crosslinking during chemical reactions, for example, a chemical reaction such as free radical polymerization to form a (co)polymer.

The term “film” or “layer” refers to a single stratum within a multilayer film.

The term “(meth)acryl” or “(meth)acrylate” with respect to a monomer, oligomer, (co)polymer or compound means a vinyl-functional alkyl ester formed as the reaction product of an alcohol with an acrylic or a methacrylic acid.

The term “crosslinked” (co)polymer refers to a (co)polymer whose (co)polymer chains are joined together by covalent chemical bonds, usually via crosslinking molecules or groups, to form a network (co)polymer. A crosslinked (co)polymer is generally characterized by insolubility but may be swellable in the presence of an appropriate solvent.

The term “cure” refers to a process that causes a chemical change, e.g., a reaction that creates a covalent bond to solidify a layer or increase its viscosity.

The term “cured (co)polymer” includes both crosslinked and uncrosslinked polymers.

The term “low refractive index” means a material or layer having a refractive index from 1.3 to 1.5.

The term “high refractive index” means a material or layer having a refractive index from 1.5-2.5.

The term “metal” includes a pure metal or a metal alloy.

The term “photoinitiator” means a material and more particularly a molecule that creates reactive species (e.g., free radicals, cations or anions) when exposed to actinic radiation (e.g., ultraviolet (UV), visible (VIS) or infrared (IR) light).

The term “vapor coating” or “vapor depositing” means applying a coating to a substrate surface from a vapor phase, for example, by evaporating and subsequently depositing onto the substrate surface a precursor material to the coating or the coating material itself. Exemplary vapor coating processes include, for example, physical vapor deposition (PVD), chemical vapor deposition (CVD), and combinations thereof.

By using the term “visible light-transmissive” with respect to a support, layer, assembly, article or device, we mean that the support, layer, assembly or device has an average transmission over the visible portion of the spectrum, Tᵥᵢₛ, of at least about 20%, measured along the normal axis.

Various exemplary embodiments of the disclosure will now be described with particular reference to the Drawings. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

In exemplary embodiments, the disclosure describes a multilayer optical film comprising a substrate and at least a first optical layer overlaying a surface of the substrate, wherein the first optical layer comprises a (co)polymer obtained by polymerizing a polymerizable composition including at least one free-radically polymerizable monomer, oligomer, or mixture thereof and at least one of the foregoing fluorinated coupling agents and optionally at least one of the foregoing fluorinated photoinitiators.

### Fluorinated Coupling Agents

The fluorinated coupling agents of the present disclosure have one of the following formulas:

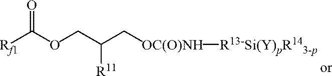

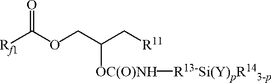

wherein:
R_{f1} is a monovalent perfluorooxyalkyl;
R¹³ is a divalent alkylene group, said alkylene groups optionally containing one or more catenary oxygen atoms;
R¹¹ is -[OC(O)-NH-R¹³]ₘ₁OC(O)CR¹⁵=CH₂ or -OC(O)-NH-R¹⁶(-OC(O)CR¹⁵=CH₂)₂; Y is a hydrolysable group;
R¹⁴ is a monovalent alkyl or aryl group;
p is 1, 2, or 3;
R¹⁵ is H or CH₃;
R¹⁶ is a polyvalent alkylene group, said polyvalent alkylene group optionally containing one or more catenary oxygen atoms; and
m1 is 1 or 0;
or

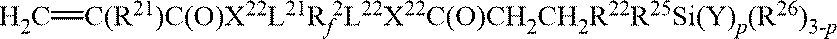

wherein:
R²¹ is H or CH₃;
X²² is -O-,-S-, or -NR²³- wherein R²³ is H or an alkyl group of 1 to 4 carbon atoms,
L²¹ and L²² are organic linking groups;
R_{f}² is a divalent perfluorooxyalkylene;
R²² is -S- or -N(R²⁴)- wherein R²⁴ is C₁-C₄ alkyl or -R²⁵Si(Y)₃;
R²⁵ is a divalent alkylene group optionally comprising one or more catenary oxygen atoms;
Y is a hydrolysable group;
R²⁶ is a non-hydrolysable group; and
p is 1, 2, or 3;
or

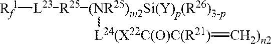

wherein:
R_{f}¹ is a monovalent perfluorooxyalkyl;
L²³ and L²⁴ are organic linking groups;
R²⁵ is a divalent alkylene group said alkylene groups optionally containing one or more catenary oxygen atoms;
Y is a hydrolysable group;
R²⁶ is a non-hydrolysable group;
p is 1, 2, or 3;
X²² is -O-, -S-, or -NR²³-, wherein R²³ is H or an alkyl group of 1 to 4 carbon atoms;
R²¹ is H or CH₃;
m2 is 1 or 2; and
n2 is 1, 2, or 3.

Suitable fluorinated coupling agents and methods of making and using such fluorinated coupling agents are disclosed in the following co-pending, co-filed U.S. Pat. Applications, the entire disclosures of which are incorporated by reference herein:
Attorney Docket No. 83052US002, titled “POLYMERIZABLE COMPOSITIONS AND COMPOUNDS COMPRISING PERFLUORINATED GROUP, HYDROLYSABLE SILANE GROUP, AND (METH)ACRYL GROUP” and
Attorney Docket No. 83094US002, titled “FLUORINATED COUPLING AGENTS AND FLUORINATED (CO)POLYMER LAYERS MADE USING THE SAME”

### Optional Fluorinated Photoinitiators

The optional fluorinated photoinitiators of the present disclosure have one of the following formulas:

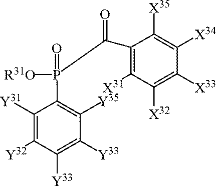

wherein:
X³¹, X³², X³³, X³⁴, X³⁵ are each independently selected from -H, -F, or -CF₃, with the proviso that at least 3 of X³¹, X³², X³³, X³⁴, X³⁵ are -F, or that at least 1 of X³¹, X³², X³³, X³⁴, X³⁵ is -CF₃;
Y³¹, Y³², Y³³, Y³⁴, Y³⁵ are each independently selected from -H, or CH₃; and
R³¹ is an alkyl group of 1 to 4 carbon atoms;
or

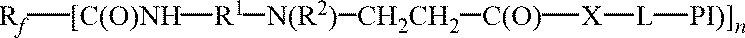

wherein:
R_{f} is a monovalent perfluorooxyalkyl group or divalent perfluorooxyalkylene group;
R¹ is an alkylene group optionally containing one or more catenary oxygen or nitrogen atoms,
R² is H or an alkyl group of 1 to 4 carbon atoms,
Xis -O-, -S-, or -NR³-, wherein R³ is H or an alkyl group of 1 to 4 carbon atoms,
L is a covalent bond or divalent organic linking group;
PI is a photoinitiator group;
n is 1 when R_{f} is a monovalent perfluorooxyalkyl group or n is 2 when R_{f} is a divalent perfluorooxyalkylene group.

In some exemplary embodiments, the fluorinated photoinitiator of formula:

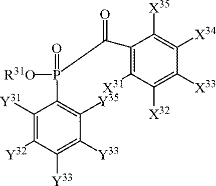

has a calculated molecular weight of no greater than 700, 600, 500, or 400 g/mole.

In other exemplary embodiments, the fluorinated photoinitiator of formula:

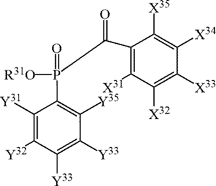

has a fluorine content of at least 10, 15, 20, 25, 30, 35, or 40 wt.%.

In further exemplary embodiments, the fluorinated photoinitiator of formula:

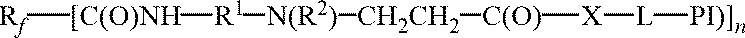

has a calculated number average molecular weight of no greater than 3000, 2500, 2000, 1500, 1000, or 500 g/mole.

In additional exemplary embodiments, the fluorinated photoinitiator of formula:

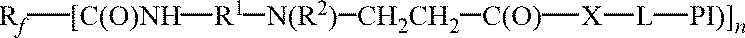

has a fluorine content of at least 30, 35, or 40 wt.%.

Suitable fluorinated photoinitiators and methods of making and using such fluorinated photoinitiators are disclosed in the following co-pending, co-filed U.S. Pat. Applications, the entire disclosures of which are hereby incorporated by reference herein:
Attorney Docket No. 83053US002, titled “COMPOUNDS COMPRISING PERFLUORINATED GROUP, PHOTOINITIATOR GROUP, AND AMIDE LINKING GROUP” and
Attorney Docket No. 83095US002, titled “FLUORINATED PHOTOINITIATORS AND FLUORINATED (CO)POLYMER LAYERS MADE USING THE SAME”

### Polymerizable Compositions

The fluorinated coupling agents and optional fluorinated photoinitiators are generally used effectively in a polymerizable composition comprising a mixture of at least one of the foregoing fluorinated coupling agents and at least one free-radically polymerizable monomer, oligomer, or mixture thereof. Preferably, at least one of the free-radically polymerizable monomers or oligomers is at least partially fluorinated.

In some exemplary embodiments, the polymerizable composition is comprised of the optional fluorinated photoinitiator of the formula:

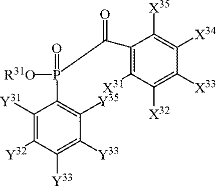

in an amount no more than about 10.0, 7.5, 5.0, 4.0 or 3.0 wt. % based on the weight of the polymerizable composition.

In still other exemplary embodiments, the polymerizable composition is comprised of the optional fluorinated photoinitiator R_{f}—[C(O)NH—R¹—N(R²)—CH₂CH₂—C(O)—X—L—PI)]ₙ in an amount no more than about 50.0, 40.0, 30.0, 20.0, 15.0, 10.0, 7.5, 5.0, 4.0 or 3.0 wt. % based on the weight of the polymerizable composition.

### Multilayer Optical Films

In exemplary embodiments, the disclosure describes a multilayer optical film comprising a substrate and at least a first layer overlaying a surface of the substrate, wherein the first layer comprises a (co)polymer obtained by polymerizing (e.g., free radical polymerization) at least one of the foregoing polymerizable compositions including at least one free-radically polymerizable monomer, oligomer, or mixture thereof and at least one of the foregoing fluorinated coupling agents, optionally including at least one of the foregoing fluorinated photoinitiators.

In some exemplary embodiments, the multilayer optical film further comprises a plurality of alternating optical layers comprised of a high refractive index optical layer overlaying the substrate and comprising an inorganic oxide, nitride, oxynitride, oxycarbide a metal or metal alloy; a (co)polymer, or a combination thereof; and an adjoining optical layer overlaying the substrate and comprising a (co)polymer.

In some advantageous embodiments, at least one of the substrate, the at least first optical layer, the at least second optical layer, or a combination thereof, further comprises a plurality of nanostructures or microstructures. In certain such embodiments, the height of the nano-scale features is at least five times larger than the width of the nano-scale features. Preferably, the width of each of the nanoscale features is less than 1,000 nm, 750 nm, 500 nm, 400 nm, 300 nm, 200 nm or even 100 nm.

In certain advantageous embodiments, the nano-scale features comprise at least one of a plurality of holes, a plurality of pillars, a plurality of recesses having a substantially flat bottom surface, a plurality of flat-topped plateau features, or a plurality of three-dimensional polygonal structures. In some such embodiments, the depth of 90% of the nano-scale features is within +/- 20 nm of a selected etch depth, which may be advantageously pre-selected.

Suitable methods and apparatus for producing such nanoscale features are disclosed in the co-pending U.S. Pat. Applications Serial Nos. 62/759,914 (filed Nov. 12, 2018) and 62/928,742 (filed Oct. 31, 2019), both titled “MATERIALS AND METHODS FOR FORMING NANO-STRUCTURES ON SUBSTRATES,” the entire disclosure of which is hereby incorporated by reference herein.

### Low Refractive Index Fluorinated (Co)Polymer Layers

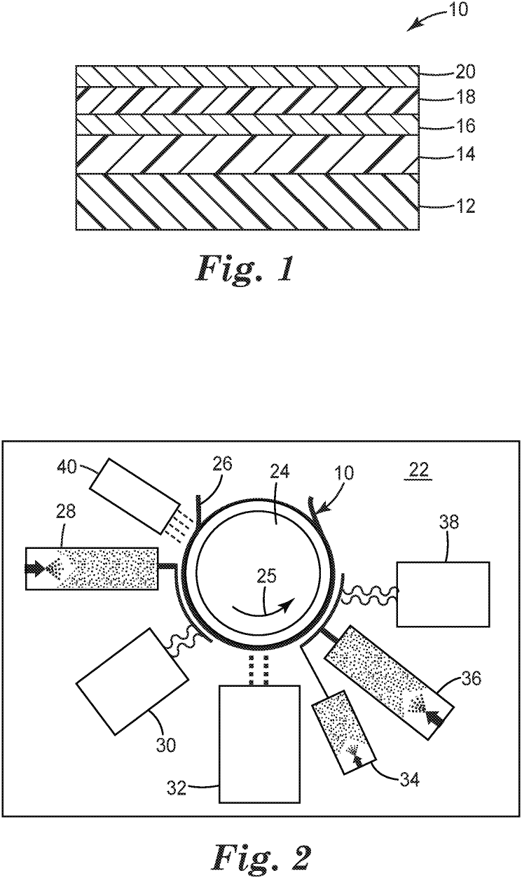

Turning to the drawings, FIG. 1 is a diagram of an exemplary multilayer optical film 10. Film 10 includes layers arranged in the following order: a substrate 12; and preferably an optical performance and/or adhesion-promoting layer 14; and at least one fluorinated (co)polymer layer 16, optionally with one or more dyads or optical pairs comprised of an additional optical performance and/or adhesion-promoting layer(s) 18 and an additional fluorinated (co)polymer layer(s) 20.

Optical performance and/or adhesion-promoting layer 14 and fluorinated (co)polymer layer 16 together form a dyad or optical pair; and optional optical performance and/or adhesion-promoting layer 18 and optional fluorinated (co)polymer layer 20 together form a second dyad or optical pair. Although only two dyads or optical pairs are shown, film 10 can include additional dyads or optical pairs of alternating optical performance and/or adhesion-promoting layers 18 and fluorinated (co)polymer layers 20 overlaying the substrate 12 between substrate 12 and the uppermost dyad or an optional optical performance and/or fluorinated (co)polymer layer 20.

### Substrates

Substrate 12 can be a flexible, visible light-transmissive substrate, such as a flexible light transmissive polymeric film. In one presently preferred exemplary embodiment, the substrates are substantially transparent, and can have a visible light transmission of at least about 50%, 60%, 70%, 80%, 90% or even up to about 100% at 550 nm.

Exemplary flexible light-transmissive substrates include thermoplastic polymeric films including, for example, polyesters, poly(meth)acrylates (e.g., polymethyl meth(meth)acrylate), polycarbonates, polypropylenes, high or low density polyethylenes, polysulfones, polyether sulfones, polyurethanes, polyamides, polyvinyl butyral, polyvinyl chloride, fluoropolymers (e.g., polyvinylidene difluoride, ethylenetetrafluoroethylene (ETFE) (co)polymers, terafluoroethylene (co)polymers, hexafluoropropylene (co)polymers, polytetrafluoroethylene, and copolymers thereof), polyethylene sulfide, cyclic olefin (co)polymers, and thermoset films such as epoxies, cellulose derivatives, polyimide, polyimide benzoxazole and polybenzoxazole.

Presently preferred polymeric films comprise polyethylene terephthalate (PET), polyethylene napthalate (PEN), heat stabilized PET, heat stabilized PEN, cyclic olefin (co)polymer (COP or COC), polyoxymethylene, polyvinylnaphthalene, polyetheretherketone, fluoropolymer, polycarbonate, polymethylmeth(meth)acrylate, poly α-methyl styrene, polysulfone, polyphenylene oxide, polyetherimide, polyethersulfone, polyamideimide, polyimide, polyphthalamide, or combinations thereof.

In some exemplary embodiments, the substrate can also be a multilayer optical film (“MOF”), such as those described in U.S. Pat. Application Publication No. US 2004/0032658 A1. In one exemplary embodiment, the films can be prepared on a substrate including PET.

The substrate may have a variety of thicknesses, e.g., about 0.01 to about 1 mm. The substrate may however be considerably thicker, for example, when a self-supporting article is desired. Such articles can conveniently also be made by laminating or otherwise joining a disclosed film made using a flexible substrate to a thicker, inflexible or less flexible supplemental support.

The (co)polymeric film can be heat-stabilized, using heat setting, annealing under tension, or other techniques that will discourage shrinkage up to at least the heat stabilization temperature when the polymeric film is not constrained.

### (Co)Polymer Layer(s)

The multilayer optical film includes at least one (co)polymer layer obtained by polymerizing (e.g., free radical polymerization) at least one of the foregoing polymerizable compositions including at least one free-radically polymerizable monomer, oligomer, or mixture thereof and at least one of the foregoing fluorinated coupling agents, optionally including at least one of the foregoing fluorinated photoinitiators.

### Fluorinated (Co)Polymer Layer(s)

### Free-Radically Polymerizable Oligomers

Returning to FIG. 1, in one aspect, for example, the at least one fluorinated (co)polymer layer 16 can be formed from various precursors, for example, fluorinated and/or non-fluorinated (meth)acrylate monomers and/or oligomers that include isobornyl (meth)acrylate, dipentaerythritol penta(meth)acrylates, epoxy (meth)acrylates, epoxy (meth)acrylates blended with styrene, di-trimethylolpropane tetra(meth)acrylates, diethylene glycol di(meth)acrylates, 1,3-butylene glycol di(meth)acrylate, penta(meth)acrylate esters, pentaerythritol tetra(meth)acrylates, pentaerythritol tri(meth)acrylates, ethoxylated (3) trimethylolpropane tri(meth)acrylates, ethoxylated (3) trimethylolpropane tri(meth)acrylates, alkoxylated trifunctional (meth)acrylate esters, dipropylene glycol di(meth)acrylates, neopentyl glycol di(meth)acrylates, ethoxylated (4) bisphenol A dimeth(meth)acrylates, tricyclodecanedimethanol di(meth)acrylates, cyclohexane dimethanol di(meth)acrylate esters, isobornyl meth(meth)acrylate, cyclic di(meth)acrylates and tris (2-hydroxy ethyl) isocyanurate tri(meth)acrylate, and urethane (meth)acrylates. Such compounds are widely available from vendors such as, for example, Sartomer Company, Exton, Pennsylvania; UCB Chemicals Corporation, Smyrna, Georgia; and Aldrich Chemical Company, Milwaukee, Wisconsin, or can be prepared by standard methods. Additional useful (meth)acrylate materials include dihydroxyhydantoin moiety-containing poly(meth)acrylates, for example, as described in U.S. Pat. No. 4,262,072 (Wendling et al.).

Preferably, the at least one fluorinated (co)polymer layer precursor comprises a fluorinated or non-fluorinated (meth)acrylate monomer.

### Fluorinated Monomers

In some embodiments, the (meth)acrylate monomers and/or oligomers include highly fluorinated monomers. Perfluorooxyalkyl and perfluoroxyalkylene compounds can be obtained by oligomerization of hexafluoropropylene oxide that result in terminal carbonyl fluoride group(s). This carbonyl fluoride(s) may be converted to an ester by reactions known to those skilled in the art. Preparation of perfluorinated methyl ester compounds are described, for example, in US 3,250,808 and US 9,718,896. Preparation of perfluorooxyalkyl and perfluoroxyalkylene compounds comprising (meth)acryl groups is also known. See for example, US 9,718,896. Examples include di(meth)acrylates including hexafluoropropylene oxide oligomer (HFPO) moieties. In certain such exemplary embodiments, the free-radically polymerizable monomer, oligomer, or combination thereof has a fluorine content of at least 25, 30 or 35 wt.%. In some of the foregoing embodiments, the polymerizable composition comprises at least of a (meth)acrylic monomer or oligomer, optionally wherein the at least one (meth)acrylic monomer or oligomer comprises the HFPO oligomer diacrylate described below of the structure:

CH₂═CHC(O)O—H₂C—(CF₃)CF—[OCF₂(CF₃)CF]ₛ—O(CF₂)ᵤO—[CF(CF₃)CF₂O]ₜ₋CF(CF₃)—CH₂—OC(O)CH═CH₂, having, for example, a number average molecular weight of about 2000 g/mole, prepared according to the synthetic method generally described in US 9,718,961 (PFE-3). Here HFPO refers to the perfluorooxyalkylene group “-HFPO-” which is —(CF₃)CF—[OCF₂(CF₃)CF]ₛ—O(CF₂)ᵤO—[CF(CF₃)CF₂O]ₜ—CF(CF₃)—, wherein u is from 2 to 6 and s and t are independently integers of 2 to 25. In some embodiments p is 3 or 4. In some embodiments, the sum of s and t is at least 3, 4, 5, 6, 7, 8, 9, or 10. In some embodiments, the sum of s and t is no greater than 24, 23, 22, 21, 20, 19, 18, 17, 16, 15, 14, 13, 12, 11, or 10. Divalent -HFPO- generally also exists as a distribution or mixture of molecules with a range of values for s and t. Thus, s and t may be expressed as an average value. Such average value is typically not an integer.

### Aminosilane Monomers

Especially useful in the practice of the presently described embodiments, as materials for Michael addition to poly(meth)acrylates, are the fluorinated and/or non-fluorinated secondary amino silanes that include N-methyl aminopropyltrimethoxy silane, N-methyl aminopropyltriethoxy silane, Bis(propyl-3-trimethoxysilane) amine, Bis(propyl-3-triethoxysilane) amine, N-butyl aminopropyltrimethoxy silane, N-butyl minopropyltriethoxy silane, N-cyclohexyl aminopropyltrimethoxy silane, N-cyclohexyl aminomethyltrimethoxy silane, N-cyclohexyl aminomethyltriethoxy silane, N-cyclohexyl aminomethyldiethoxy monomethyl silane.

Other aminosilanes useful in the practice of this disclosure are described in U.S. Pat. No. 4,378,250 (Treadway et al.) and include aminoethyltriethoxysilane, β-aminoethyltrimethoxysilane, β-aminoethyltriethoxysilane, β-aminoethyltributoxysilane, β-aminoethyltripropoxysilane, α-amino-ethyltrimethoxysilane, α-aminoethyltriethoxy-silane, γ-aminopropyltrimethoxysilane, γ-aminopropyltrimethoxysilane, y-aminopropyl-triethoxysilane, γ-aminopropyltributoxysilane, γ-aminopropyltripropoxysilane, β-aminopropyltrimethoxysilane, β-aminopropyltriethoxysilane, β-aminopropyl-tripropoxysilane, β-aminopropyltributoxysilane, α-aminopropyltrimethoxysilane, α-amino-propyltriethoxysilane, α-aminopropyltributoxysilane, and α-aminopropyl-tripropoxysilane.

Minor amounts (< 20 mole percent) of catenary nitrogen-containing aminosilanes may also be used, including those described in U.S. 4,378,250 (Treadway et al. N-(β-aminoethyl)- β-aminoethyltrimethoxysilane, N-(β-aminoethyl)- β-aminoethyltriethoxysilane, N-(β-aminoethyl)- β-aminoethyltripropoxysilane, N-(β-aminoethyl)-α-aminoethyltrimethoxysilane, N-(β-aminoethyl)-α-aminoethyl-triethoxysilane, N-(β-aminoethyl)- α-aminoethyltripropoxysilane, N-(β-aminoethyl)-β-aminopropyltrimethoxysilane, N-(β-aminoethyl)- γ-aminopropyltriethoxysilane, N-(β-aminoethyl)-γ-aminopropyltripropoxysilane, N-(β-aminoethyl)- γ-aminopropyl-trimethoxysilane, N-(β-aminoethyl)-β-aminopropyltriethoxysilane, N-(β-aminoethyl)-β-aminopropyltripropoxysilane, N-(γ-aminopropyl)-β-aminoethyltrimethoxysilane, N-(γ-aminopropyl)- β-aminoethyltriethoxysilane, N-(γ-aminopropyl)-β-aminoethyl-tripropoxysilane, N-methylaminopropyltrimethoxysilane, β-aminopropylmethyl-diethoxysilane, and γ-diethylene triaminepropyltriethoxysilane.

### Thiosilane Compounds

Also useful in the practice of the presently described embodiments, as materials for Michael addition to poly(meth)acrylates, are fluorinated and/or non-fluorinated thiosilanes. Examples of silane compounds comprising hydrolysable groups and a mercapto group include for example 3-mercaptopropyltriethoxysilane; 3-mercaptopropyl-trimethoxysilane; 11-mercaptoundecyltrimethoxysilane; s-(octanoyl)mercapto-propyltriethoxysilane; (mercaptomethyl)methyldiethoxysilane; and 3-mercaptopropylmethyldimethoxysilane.

### Isocyanate Functional Silanes and (Meth)Acrylates

Isocyanato functional acrylates and silanes may be used in the practice of the presently described embodiments. Examples of suitable isocyanate functional (meth)acrylates include isocyanatoethyl methacrylate, isocyanatoethoxyethyl methacrylate, isocyanatoethyl acrylate, and 1,1-(bisacryloyloxymethyl) ethyl isocyanate, which are for instance commercially available from Showa Denko (Tokyo, Japan). Examples of suitable isocyanate functional silanes include isocyanatopropyltrimethoxysilane, and isocyanatopropyltriethoxysilane, available as Silquest A-Link35 and Silquest A-Link A-1310, respectively from Momentive (Waterford, NY).

Returning to FIG. 1, in some exemplary embodiments, the at least one (co)polymer layer 16 may additionally include any fluorinated (co)polymer suitable for deposition in a thin film.

The at least one fluorinated (co)polymer layer 16 can be formed by applying a layer of a monomer or oligomer to the substrate and crosslinking the layer to form the (co)polymer in situ, e.g., by flash evaporation and vapor deposition of a radiation-crosslinkable monomer, followed by crosslinking using, for example, an electron beam apparatus, UV light source, electrical discharge apparatus or other suitable device. Coating efficiency can be improved by cooling the substrate.

The monomer or oligomer can also be applied to the substrate 12 using conventional coating methods such as roll coating (e.g., gravure roll coating) or spray coating (e.g., electrostatic spray coating), then crosslinked as set out above. The at least one fluorinated (co)polymer layer 16 can also be formed by applying a layer containing an oligomer or (co)polymer in solvent and drying the thus-applied layer to remove the solvent. Plasma Enhanced Chemical Vapor Deposition (PECVD), Chemical Vapor Deposition (CVD), initiated Chemical Vapor Deposition (iCVD), Plasma Polymerization, and Molecular Layer Deposition (MLD) may also be employed in some cases.

Preferably, the at least one fluorinated (co)polymer layer 16 is formed by flash evaporation and vapor deposition followed by crosslinking in situ, e.g., as described in U.S. Pat. Nos. 4,696,719 (Bischoff), 4,722,515 (Ham), 4,842,893 (Yializis et al.), 4,954,371 (Yializis), 5,018,048 (Shaw et al.), 5,032,461(Shaw et al.), 5,097,800 (Shaw et al.), 5,125,138 (Shaw et al.), 5,440,446 (Shaw et al.), 5,547,908 (Furuzawa et al.), 6,045,864 (Lyons et al.), 6,231,939 (Shaw et al. and 6,214,422 (Yializis); in PCT International Publication No. WO 00/26973 (Delta V Technologies, Inc.); in D. G. Shaw and M. G. Langlois, “A New Vapor Deposition Process for Coating Paper and Polymer Webs”, 6th International Vacuum Coating Conference (1992); in D. G. Shaw and M. G. Langlois, “A New High Speed Process for Vapor Depositing Acrylate Thin Films: An Update”, Society of Vacuum Coaters 36th Annual Technical Conference Proceedings (1993); in D. G. Shaw and M. G. Langlois, “Use of Vapor Deposited Acrylate Coatings to Improve the Barrier Properties of Metallized Film”, Society of Vacuum Coaters 37th Annual Technical Conference Proceedings (1994); in D. G. Shaw, M. Roehrig, M. G. Langlois and C. Sheehan, “Use of Evaporated Acrylate Coatings to Smooth the Surface of Polyester and Polypropylene Film Substrates”, RadTech (1996); in J. Affinito, P. Martin, M. Gross, C. Coronado and E. Greenwell, “Vacuum Deposited Polymer/Metal Multilayer optical films for Optical Application”, Thin Solid Films 270, 43-48 (1995); and in J. D. Affinito, M. E. Gross, C. A. Coronado, G. L. Graff, E. N. Greenwell and P. M. Martin, “Polymer-Oxide Transparent Barrier Layers”, Society of Vacuum Coaters 39th Annual Technical Conference Proceedings (1996).

In some exemplary embodiments, the smoothness and continuity of the at least one fluorinated (co)polymer layer 16 (and optionally also each oxide layer) and its adhesion to the underlying substrate or layer may be enhanced by appropriate pretreatment. Examples of a suitable pretreatment regimen include an electrical discharge in the presence of a suitable reactive or non-reactive atmosphere (e.g., plasma, glow discharge, corona discharge, dielectric barrier discharge or atmospheric pressure discharge); chemical pretreatment or flame pretreatment. These pretreatments help make the surface of the underlying layer more receptive to formation of the subsequently applied polymeric (or inorganic) layer. Plasma pretreatment can be particularly useful.

The desired chemical composition and thickness of the at least one fluorinated (co)polymer layer will depend in part on the design target refractive index and optical performance. The thickness range is from a fraction of a quarter-wave optical thickness for multilayer thin film optical coatings to 10 microns thick or thicker in some nano- or micro-structured optical constructions.

In some exemplary embodiments, a separate optical performance and/or adhesion-promoting layer 18, which may have a different composition than the at least one fluorinated (co)polymer layer 16, the optical performance and/or adhesion-promoting layer 14, and/or the optional additional fluorinated (co)polymer layer 20, may also be used atop the substrate or an underlying layer to improve adhesion. The optical and/or adhesion-promoting layer 18 can be, for example, a separate polymeric layer or a metal-containing layer such as a layer of metal, metal oxide, metal nitride or metal oxynitride. The optical and/or adhesion-promoting layer 18 may have a thickness of a few nm (e.g., 1 or 2 nm) to about 50 nm, and can be thicker if desired.

The desired chemical composition and thickness of the at least one fluorinated (co)polymer layer will depend in part on the nature and surface topography of the substrate. The thickness preferably is sufficient to provide a smooth, defect-free surface to which the optional subsequent adhesion-promoting layer can be applied. For example, the at least one fluorinated (co)polymer layer may have a thickness of a few nm (e.g., 2 or 3 nm) to about 5 micrometers, and can be thicker if desired.

As described elsewhere, the multilayer optical film can include an adhesion-promoting layer deposited directly on a substrate that includes a moisture sensitive device, a process often referred to as direct encapsulation. The moisture sensitive device can be, for example, an organic, inorganic, or hybrid organic/ inorganic semiconductor device including, for example, a photovoltaic device such as a copper indium gallium di-selenide (CIGS) photovoltaic device; a display device such as an organic light emitting diode (OLED), electrochromic, or an electrophoretic display; an OLED or other electroluminescent solid state lighting device, or others. Flexible electronic devices can be encapsulated directly with a gradient composition adhesion-promoting layer as described below. For example, the devices can be attached to a flexible carrier substrate, and a mask can be deposited to protect electrical connections from the adhesion-promoting layer deposition. The at least one fluorinated (co)polymer layer 16, the optical and/or adhesion-promoting layers 14 and 18 and the fluorinated (co)polymer layer 20 can be deposited as described further below, and the mask can then be removed, exposing the electrical connections.

### High Refractive Index Layers

As described elsewhere, the multilayer optical film can include a high refractive index layer that may be deposited overlaying a substrate, or overlaying a low refractive index fluorinated (co)polymer layer. The at least one low refractive index fluorinated (co)polymer layer 16, and the high refractive index layer 14 can be deposited as described further below.

Thus, preferably, the multilayer optical film includes at least one high refractive index layer 14. The high refractive index layer can comprise inorganic, organic, or hybrid inorganic/organic material. The high refractive index layer preferably comprises at least one inorganic material. Suitable inorganic materials include oxides, nitrides, carbides or borides of different atomic elements, metals and metal alloys. Presently preferred inorganic materials included in the high refractive index layer comprise oxides, nitrides, carbides or borides of atomic elements from Groups IIA, IIIA, IVA, VA, VIA, VIIA, IB, or IIB, metals of Groups IIIB, IVB, or VB, rare-earth metals, or combinations thereof. In some exemplary embodiments, high refractive index oxide layers comprising titanium, zirconium, hafnium, vanadium, niobium, tantalum, cerium or a combination thereof are preferred.

### Oxide Layers

As described elsewhere, the multilayer optical film can include an oxide layer that may be deposited overlaying a substrate that includes a moisture sensitive device, a process often referred to as direct encapsulation.

In some particular exemplary embodiments, an inorganic layer, more preferably an inorganic oxide layer, may be applied to the uppermost fluorinated (co)polymer layer. Preferably, the oxide layer comprises titanium oxide, niobium oxide, or silicon aluminum oxide.

In some exemplary embodiments, the composition of the oxide layer may change in the thickness direction of the layer, i.e. a gradient composition. In such exemplary embodiments, the oxide layer preferably includes at least two inorganic materials, and the ratio of the two inorganic materials changes throughout the thickness of the oxide layer. The ratio of two inorganic materials refers to the relative proportions of each of the inorganic materials. The ratio can be, for example, a mass ratio, a volume ratio, a concentration ratio, a molar ratio, a surface area ratio, or an atomic ratio.

The resulting gradient oxide layer is an improvement over homogeneous, single component layers. Additional benefits in optical properties can also be realized when combined with thin, vacuum deposited fluorinated (co)polymer layers. A multilayer gradient inorganic-(co)polymer barrier stack can be made to enhance optical properties. The multilayer optical film can be fabricated by deposition of the various layers onto the substrate, in a roll-to-roll vacuum chamber similar to the system described in U.S. Pat. Nos. 5,440,446 (Shaw et al.) and 7,018,713 (Padiyath, et al.). The deposition of the layers can be in-line, and in a single pass through the system. In some cases, the multilayer optical film can pass through the system several times, to form a multilayer optical film having several optical pairs.

High refractive index layers also can comprise organic materials. Suitable organic materials include (co)polymers, particle-filled (co)polymers, small molecule organic solid materials. Preferred particle-filled (co)polymers comprise silica, zirconia and/or titania nanoparticles in acrylate (co)polymers, as described in U.S. Pat. No. 7,547,476.

High refractive index layers can comprise inorganic/organic hybrid materials. Preferred inorganic/organic hybrid materials include organotitanate polymers such as polybutyltitanate.

For purposes of clarity, the high refractive index layer 14 described in the following discussion is directed toward a composition of oxides; however, it is to be understood that the composition can include any of the oxides, nitrides, carbides, borides, oxynitrides, oxyborides, metals, metal alloys, organic, or inorganic/organic hybrid materials and the like described above.

In one embodiment of the oxide layer 14, the first inorganic material is silicon oxide, and the second inorganic material is aluminum oxide. In this embodiment, the atomic ratio of silicon to aluminum changes throughout the thickness of the oxide layer, e.g., there is more silicon than aluminum near a first surface of the oxide layer, gradually becoming more aluminum than silicon as the distance from the first surface increases. In one embodiment, the atomic ratio of silicon to aluminum can change monotonically as the distance from the first surface increases, i.e., the ratio either increases or decreases as the distance from the first surface increases, but the ratio does not both increase and decrease as the distance from the first surface increases. In another embodiment, the ratio does not increase or decrease monotonically, i.e. the ratio can increase in a first portion, and decrease in a second portion, as the distance from the first surface increases. In this embodiment, there can be several increases and decreases in the ratio as the distance from the first surface increases, and the ratio is non-monotonic. A change in the inorganic oxide concentration from one oxide species to another throughout the thickness of the oxide layer 14 results in improved optical performance.

The gradient composition can be made to exhibit other unique optical properties. The gradient change in composition of the layer produces corresponding change in refractive index through the layer. The materials can be chosen such that the refractive index can change from high to low, or vice versa. For example, going from a high refractive index to a low refractive index can allow light traveling in one direction to easily pass through the layer, while light travelling in the opposite direction may be reflected by the layer. The refractive index change can be used to design layers to enhance light extraction from a light emitting device being protected by the layer. The refractive index change can instead be used to pass light through the layer and into a light harvesting device such as a solar cell. Other optical constructions, such as band pass filters, can also be incorporated into the multilayer optical film.

In order to promote silane bonding to the oxide surface, it may be desirable to form hydroxyl silanol (Si—OH) groups on a freshly sputter deposited silicon dioxide (SiO₂) layer. The amount of water vapor present in a multi-process vacuum chamber can be controlled sufficiently to promote the formation of Si—OH groups in high enough surface concentration to provide increased bonding sites. With residual gas monitoring and the use of water vapor sources the amount of water vapor in a vacuum chamber can be controlled to ensure adequate generation of Si—OH groups.

### Formation of (Co)Polymer Layers

The (meth)acrylate vapor deposition process is limited to chemistries that are pumpable (liquid-phase with an acceptable viscosity); that can be atomized (form small droplets of liquid), flash evaporated (high enough vapor pressure under vacuum conditions), condensable (vapor pressure, molecular weight), and can be cross-linked in vacuum (molecular weight range, reactivity, functionality).

### Vapor Coating, Compositions

The vapor coating compositions may be prepared via mixing. The fluorinated silane coupling agents and optional photoinitiators of this disclosure are generally soluble in fluorinated monomers and/or fluorinated solvents, forming clear solutions.

### Processes for Making Layers and Multilayer Optical Films

In another aspect, the disclosure describes a process for making a layer or a multilayer optical film.

In one exemplary presently preferred embodiment, the disclosure describes a process for making a multilayer optical film, the process including:

step (a) comprises depositing an oxide onto the substrate to form the optical performance and/or adhesion-promoting layer, wherein depositing is achieved using sputter deposition, reactive sputtering, plasma enhanced chemical vapor deposition, or a combination thereof.

In other exemplary embodiments, step (b) comprises:
(i) evaporating a at least one fluorinated (co)polymer layer precursor;
(ii) condensing the evaporated at least one fluorinated (co)polymer layer precursor onto the at least one adhesion-promoting or high refractive index layer; and
(iii) curing the evaporated at least one fluorinated (co)polymer layer precursor to form the at least one fluorinated (co)polymer layer.

In further exemplary embodiments, the process further comprises sequentially repeating steps (a) and (b) to form a plurality of alternating layers (i.e. dyads or optical pairs) of the optical performance and/or adhesion-promoting layer and the fluorinated (co)polymer layer on the at least one optical performance and/or adhesion-promoting layer.

FIG. 2 is a diagram of a system 22, illustrating a process for making multilayer optical film 10. System 22 is contained within an inert environment and includes a chilled drum or roller 24 for receiving and moving the substrate 12 (FIG. 1), as represented by a substrate film 26, thereby providing a moving web on which to form optical layers. Preferably, an optional nitrogen plasma treatment unit 40 may be used to plasma treat or prime substrate film 26 in order to improve adhesion of the at least one fluorinated (co)polymer layer 16 (FIG. 1) to substrate 12 (FIG. 1) or the at least one adhesion-promoting or optical performance layer 14 (FIG. 1) to substrate 12 (FIG. 1).

An oxide sputter unit 32 applies an oxide to form layer 14 (FIG. 1) as drum 24 advances film 26. An evaporator 36 applies an at least one fluorinated (co)polymer layer precursor preferably from a polymerizable composition comprising a mixture of at least one of the foregoing fluorinated coupling agents and at least one free-radically polymerizable monomer, oligomer, or mixture thereof, and optionally at least one of the foregoing fluorinated photoinitiators, which is cured by curing unit 38 to form at least one fluorinated (co)polymer layer 16 (FIG. 1) as drum 24 advances the film 26 in a direction shown by arrow 25.

For additional optional dyads or optical pairs comprised of alternating optical performance and/or adhesion-promoting layer 18 and alternating fluorinated (co)polymer layers 20, drum 24 can rotate in a reverse direction opposite arrow 25 and then advance film 26 again to apply the additional alternating adhesion-promoting and/or optical performance layer and at least one fluorinated (co)polymer layer, and that sub-process can be repeated for as many alternating layers as desired or needed. Alternatively, the layers may be applied sequentially in a roll-to-roll process using a substrate in the form of a substantially continuous web.

Optionally, once the at least one optical performance and/or adhesion-promoting (e.g. oxide) layers (14 and optionally 18) and fluorinated (co)polymer layers (16 and optionally 20) have been applied to the substrate film 12, drum or roller 24 further advances the film, and evaporator 36 may deposit an additional optical layer overlaying the optical stack. Co-depositing the fluorinated coupling agent and optionally the fluorinated photoinitiator and the fluorinated monomer, oligomer, or mixture can involve sequentially evaporating the fluorinated coupling agent and the fluorinated monomer, oligomer, or mixture from separate sources, or co-evaporating a mixture of the fluorinated coupling agent and the fluorinated monomer, oligomer, or mixture.

An optional additional evaporator 34 also may be used to provide other co-reactants or co-monomers (e.g. additional (meth)acryloyl compounds) which may be useful in forming a fluorinated (co)polymer layer (e.g., 16 or 20, FIG. 1). In some embodiments, a fluorinated or non-fluorinated coupling agent and optionally a fluorinated or non-fluorinated photoinitiator can be evaporated in additional evaporator 34 while evaporating the fluorinated free-radically polymerizable monomer, oligomer, or mixture and optionally the fluorinated photoinitiator in evaporator 36. In this way, the coupling agent and the fluorinated (co)polymer materials are sequentially evaporated from separate liquid sources and deposited. Preferably, the sequential combination of the fluorinated coupling agent and the fluorinated free-radically polymerizable monomer, oligomer, or mixture comprises fluorinated coupling agent in an amount of no more than about 50, 40, 30, 20 or 10 wt. % based on the weight of the polymerizable composition.

For additional dyads or optical pairs comprised of alternating fluorinated (co)polymer layers 20 and optical performance and/or adhesion-promoting layers 18, drum 24 can rotate in a reverse direction opposite arrow 25 and then advance substrate film 26 again to apply the additional layers, and that sub-process can be repeated for as many alternating optical pairs or dyads as desired or needed.

In certain presently preferred embodiments, reacting the polymerizable composition to form a fluorinated (co)polymer layer (16 or 20, FIG. 1) occurs at least in part on the substrate film 12.

The optical performance and/or adhesion-promoting layer 14 or 18 can be formed using techniques employed in the film metalizing art such as sputtering (e.g., cathode or planar magnetron sputtering), evaporation (e.g., resistive or electron beam evaporation), chemical vapor deposition, plating and the like.

In one aspect, the optical performance and/or adhesion-promoting layer 14 or 18 is formed using sputtering, e.g., reactive sputtering. Enhanced moisture and/or oxygen barrier properties may be obtained when the adhesion-promoting barrier layer is formed by a high energy deposition technique such as sputtering compared to lower energy techniques such as conventional chemical vapor deposition processes. Without being bound by theory, it is believed that the enhanced properties are due to the condensing species arriving at the substrate with greater kinetic energy as occurs in sputtering, leading to a lower void fraction as a result of compaction.

In some exemplary embodiments, the sputter deposition process can use dual targets powered by an alternating current (AC) power supply in the presence of a gaseous atmosphere having inert and reactive gasses, for example argon and oxygen, respectively. The AC power supply alternates the polarity to each of the dual targets such that for half of the AC cycle one target is the cathode and the other target is the anode. On the next cycle the polarity switches between the dual targets. This switching occurs at a set frequency, for example about 40 kHz, although other frequencies can be used. Oxygen that is introduced into the process forms adhesion-promoting layers on both the substrate receiving the inorganic composition, and also on the surface of the target. The dielectric oxides can become charged during sputtering, thereby disrupting the sputter deposition process. Polarity switching can neutralize the surface material being sputtered from the targets, and can provide uniformity and better control of the deposited material.

In further exemplary embodiments, each of the targets used for dual AC sputtering can include a single metal or nonmetal element, or a mixture of metal and/or nonmetal elements. A first portion of the adhesion-promoting layer closest to the moving substrate is deposited using the first set of sputtering targets. The substrate then moves proximate the second set of sputtering targets and a second portion of the adhesion-promoting layer is deposited on top of the first portion using the second set of sputtering targets. The composition of the adhesion-promoting layer changes in the thickness direction through the layer.

In additional exemplary embodiments, the sputter deposition process can use targets powered by direct current (DC) power supplies in the presence of a gaseous atmosphere having inert and reactive gasses, for example argon and oxygen, respectively. The DC power supplies supply power (e.g. pulsed power) to each cathode target independent of the other power supplies. In this aspect, each individual cathode target and the corresponding material can be sputtered at differing levels of power, providing additional control of composition through the layer thickness. The pulsing aspect of the DC power supplies is similar to the frequency aspect in AC sputtering, allowing control of high rate sputtering in the presence of reactive gas species such as oxygen. Pulsing DC power supplies allow control of polarity switching, can neutralize the surface material being sputtered from the targets, and can provide uniformity and better control of the deposited material.

In one particular exemplary embodiment, improved control during sputtering can be achieved by using a mixture, or atomic composition, of elements in each target, for example a target may include a mixture of aluminum and silicon. In another embodiment, the relative proportions of the elements in each of the targets can be different, to readily provide for a varying atomic ratio throughout the adhesion-promoting layer. In one embodiment, for example, a first set of dual AC sputtering targets may include a 90/10 mixture of silicon and aluminum, and a second set of dual AC sputtering targets may include a 75/25 mixture of aluminum and silicon. In this embodiment, a first portion of the adhesion-promoting layer can be deposited with the 90%Si/10%Al target, and a second portion can be deposited with the 75%Al/25%Si target. The resulting adhesion-promoting layer has a gradient composition that changes from about 90% Si to about 25% Si (and conversely from about 10% A1 to about 75% A1) through the thickness of the adhesion-promoting layer.

In typical dual AC sputtering, homogeneous adhesion-promoting layers are formed, and barrier performance from these homogeneous adhesion-promoting layers suffer due to defects in the layer at the micro and nano-scale. One cause of these small scale defects is inherently due to the way the oxide grows into grain boundary structures, which then propagate through the thickness of the film. Without being bound by theory, it is believed several effects contribute to the improved barrier properties of the gradient composition barriers described herein. One effect can be that greater densification of the mixed oxides occurs in the gradient region, and any paths that water vapor could take through the oxide are blocked by this densification. Another effect can be that by varying the composition of the oxide materials, grain boundary formation can be disrupted resulting in a microstructure of the film that also varies through the thickness of the adhesion-promoting layer. Another effect can be that the concentration of one oxide gradually decreases as the other oxide concentration increases through the thickness, reducing the probability of forming small-scale defect sites. The reduction of defect sites can result in a coating having reduced transmission rates of water permeation.

The vapor deposited layers or films can be subjected to post-treatments such as heat treatment, ultraviolet (UV) or vacuum UV (VUV) treatment, or plasma treatment. Heat treatment can be conducted by passing the film through an oven or directly heating the film in the coating apparatus, e.g., using infrared heaters or heating directly on a drum. Heat treatment may for example be performed at temperatures from about 30° C. to about 200° C., about 35° C. to about 150° C., or about 40° C. to about 70° C.

Other functional layers or coatings that can be added to the inorganic or hybrid film include an optional layer or layers to make the film more rigid. The uppermost layer of the film is optionally a suitable protective layer, such as optional inorganic layer 18. If desired, the protective layer can be applied using conventional coating methods such as roll coating (e.g., gravure roll coating) or spray coating (e.g., electrostatic spray coating), then crosslinked using, for example, UV radiation. The protective layer can also be formed by flash evaporation, vapor deposition and crosslinking of a monomer as described above. Volatilizable (meth)acrylate monomers are suitable for use in such a protective layer. In a specific embodiment, volatilizable (meth)acrylate monomers are employed.

### Articles Incorporating Multilayer Optical Films

In a further aspect, the disclosure describes methods of using a multilayer optical film made as described above in an article, wherein the article is selected from a photovoltaic device, a display device, a solid-state lighting device, a sensor, a medical or biological diagnostic device, or a combination thereof.

Presently preferred articles incorporating such multilayer optical films include flexible thin film (e.g. copper indium gallium diselenide, CIGS) and organic photovoltaic solar cells, and organic light emitting diodes (OLED) used in displays and solid-state lighting. Currently these applications are generally limited to non-flexible glass substrates used as vapor barriers.

Exemplary embodiments of the disclosed methods can enable the formation of multilayer optical films that exhibit superior mechanical properties such as elasticity and flexibility and which optionally may have low oxygen or water vapor transmission rates. Multilayer optical films according to the present disclosure also may have an oxygen transmission rate (OTR) less than about 1 cc/m²-day, less than about 0.5 cc/m²-day, or less than about 0.1 cc/m²-day. Substrates having a multilayer optical film formed using the disclosed method can have an water vapor transmission rate (WVTR) less than about 10 cc/m²-day, less than about 5 cc/m²-day, or less than about 1 cc/m²-day.

Exemplary multilayer optical films are comprised of at least one fluorinated (co)polymer optical layer and at least one optical and/or adhesion-promoting layer, as described above. In some exemplary embodiments, the disclosed films can have a plurality of dyads or optical pairs of (co)polymer optical layer and at least one optical and/or adhesion-promoting layers.

Exemplary embodiments of multilayer optical films according to the present disclosure are preferably transmissive to both visible and infrared light. The term “transmissive to visible and infrared light” as used herein can mean having an average transmission over the visible and infrared portion of the spectrum of at least about 75% (in some embodiments at least about 80, 85, 90, 92, 95, 97, or 98%) measured along the normal axis. In some embodiments, the visible and infrared light-transmissive assembly has an average transmission over a range of 400 nm to 1400 nm of at least about 75% (in some embodiments at least about 80, 85, 90, 92, 95, 97, or 98%). Visible and infrared light-transmissive assemblies are those that do not interfere with absorption of visible and infrared light, for example, by photovoltaic cells.

In some exemplary embodiments, the visible and infrared light-transmissive assembly has an average transmission over a range wavelengths of light that are useful to a photovoltaic cell of at least about 75% (in some embodiments at least about 80, 85, 90, 92, 95, 97, or 98%). The first and second polymeric film substrates, pressure sensitive adhesive layer, and multilayer optical film can be selected based on refractive index and thickness to enhance transmission to visible and infrared light. Suitable methods for selecting the refractive index and/or thickness to enhance transmission to visible and/or infrared light are described in copending PCT International Publication Nos. WO 2012/003416 and WO 2012/003417.

Exemplary multilayer optical films according to the present disclosure are typically flexible. The term “flexible” as used herein refers to being capable of being formed into a roll. In some embodiments, the term “flexible” refers to being capable of being bent around a roll core with a radius of curvature of up to 7.6 centimeters (cm) (3 inches), in some embodiments up to 6.4 cm (2.5 inches), 5 cm (2 inches), 3.8 cm (1.5 inch), or 2.5 cm (1 inch). In some embodiments, the flexible assembly can be bent around a radius of curvature of at least 0.635 cm (¼ inch), 1.3 cm (½ inch) or 1.9 cm (¾ inch).

Exemplary multilayer optical films according to the present disclosure generally do not exhibit delamination or curl that can arise from thermal stresses or shrinkage in a multilayer structure. Herein, curl is measured using a curl gauge described in “Measurement of Web Curl” by Ronald P. Swanson presented in the 2006 AWEB conference proceedings (Association of Industrial Metallizers, Coaters and Laminators, Applied Web Handling Conference Proceedings, 2006). According to this method curl can be measured to the resolution of 0.25 m⁻¹ curvature.

In some embodiments, multilayer optical films according to the present disclosure exhibit curls of up to 7, 6, 5, 4, or 3 m⁻¹. From solid mechanics, the curvature of a beam is known to be proportional to the bending moment applied to it. The magnitude of bending stress is in turn is known to be proportional to the bending moment. From these relations the curl of a sample can be used to compare the residual stress in relative terms. Barrier films also typically exhibit high peel adhesion to EVA, and other common encapsulants for photovoltaics, cured on a substrate. The properties of the multilayer optical films disclosed herein typically are maintained even after high temperature and humidity aging.

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### EXAMPLES

All parts, percentages, and ratios in the examples are by weight, unless noted otherwise. Solvents and other reagents used were obtained from Sigma-Aldrich Chemical Company; Milwaukee, WI unless specified differently.

### Materials

Table 1 lists the materials used to prepare fluorinated coupling agents according to the foregoing disclosure:

TABLE 1

Materials Used in the Preparative Examples and Examples

| Short Name | Long Name | CAS Number | Source |
|---|---|---|---|
| 4-Angstrom Molecular Sieves | NA | 109-87-5 | Sigma-Aldrich |
| Acryloyl Chloride | NA | 814-68-6 | Sigma-Aldrich |
| Aminoethanol | 2-aminoethanol | 141-43-5 | Sigma-Aldrich |
| BEI | 1,1-Bis(acryloyloxymethyl)ethyl isocyanate | 886577-76-0 | Showa Denko |
| BHT | Butylated hydroxytoluene | 128-37-0 | Sigma-Aldrich |
| GMA | Glycidyl Methacrylate (mixture of isomers) | 106-91-2 | TCI America |
| Glycidol | Oxiranylmethanol (mixture of isomers) | 556-52-5 | Aldrich |
| PFTDA | Perfluoro-3,6,9-trioxatridecanoic Acid | 330562-41-9 | Oakwood Chemicals |
| PFNA | Perfluorononanoic Acid | 375-95-1 | Oakwood Chemicals |
| DBTDL | Dibutyltin Dilaurate | 77-58-7 | TCI America |
| TEA | Triethylamine | 121-44-8 | EMD Millipore |
| K90 | (2-(3-trimethoxysilylpropyl carbamoyloxy)ethyl prop-2-enoate | | 3 M Company |
| Darocur™ 1173 | 2-Hydroxy-2-methylpropiophenone | 7473-98-5 | Sigma-Aldrich |
| AEAPTMS, Silquest™ A-1120 | N-(2-aminoethyl)-3-aminopropyltrimethoxysilane | 1760-24-3 | Momentive Performance Materials |
| (B-PTMS), Silquest™ A-1170 | Bis-(propyltrimethoxysilyl) amine | 82985-35-1 | Momentive Performance Materials |
| DCM | Dichloromethane, CH₂Cl₂ | | EMD Millipore |
| G-AC-MAC | 1-(acryloyloxy)-3-(methacryloyloxy)-2-propanol | 1709-71-3 | TCI America |
| HFPO Oligomer Diacrylate Mₙ = 2000 g/mole | CH₂═CHC(O)O—H₂C—(CF₃)CF— [OCF₂(CF₃)CF]ₛ—O(CF₂)ᵤO—[CF(CF₃)CF₂O]ₜ— CF(CF₃)—CH₂—OC(O)CH═CH₂ | | Prepared according to the synthetic method generally described in US 9,718,961. (PFE-3) |
| HFPO dihydrodiol-alpha, omega | HO—H₂C—(CF₃)CF—[OCF₂(CF₃)CF]_{S}— O(CF₂)ᵤO—[CF(CF₃)CF₂O]ₜ₋CF₂(CF₃)—CH₂— OH | | Prepared by a method similar to that shown in US 9,718,896 Column 16, lines 32-55. |
| HFPO di(methyl ester)-alpha, omega | CH₃O(O)C—(CF₃)CF—[OCF₂(CF₃)CF]ₛ O(CF₂)ᵤO—[CF(CF₃)CF₂O]ₜ—CF(CF₃)— C(O)OCH₃ | | Prepared by a method similar to that shown in US 9,718,896 Column 16, lines 36-46 |
| HFPO methyl ester | C₃F₇O[CF(CF₃)CF₂O]ₙCF(CF₃)—C(O)OCH₃ | | Prepared by a method similar that in US 3,250,808, followed by fractional distillation. |
| Hunig’s Base | di-isopropylethylamine | 7087-68-5 | Alfa Aesar |
| IEA | Isocyanatoethyl Acrylate | 13641-96-8 | Showa Denko |
| IEMA | Isocyanatoethyl Methacrylate | 30674-80-7 | Showa Denko |
| IPTES | 3-Isocyanatopropyl-triethoxysilane | 24801-88-5 | Acros Organics |
| IPTMS | 3-Isocyanatopropyl-trimethoxysilane | 15396-00-6 | Gelest |
| Magnesium sulfate | NA | 7487-88-9 | Sigma-Aldrich |
| MPTMS | (3-mercaptopropyl)trimethoxysilane | 4420-74-0 | Alfa Aesar |
| MTBE | Methyl t-butyl ether | 1634-04-4 | EMD Millipore |
| N-Me-APTMS | N-methyl-3-aminopropyltrimethoxysilane | 3069-25-8 | Oakwood Chemical |
| Novec® 7200 | C₄F₉OCH₂CH₃ | | 3 M Company |
| Serinol | H₂_{N}—CH(CH2OH)₂ | 534-03-2 | Sigma-Aldrich |
| THF | Tetrahydrofuran | 109-99-9 | EMD Millipore |
| TMS chloride | Trimethylsilyl chloride | 75-77-4 | Sigma-Aldrich |
| TEA | Triethylamine | 121-44-8 | Sigma-Aldrich |
| TEMPO | 2,6,6,6-Tetramethyl-1-piperidinyloxy, free radical, | 2564-83-2 | Sigma-Aldrich |
| TFT | 1,1,1-trifluorotoluene | 98-08-8 | Sigma-Aldrich |
| XK-672 | Zn based catalyst obtained as “K-KAT XK-672” | | King Industries |
| PFDHA | Perfluoro-3,6-dioxaheptanoic acid | 151772-58-6 | Oakwood Chemicals |
| FC-SO3H | Nonafluorobutane-1-sulfonic acid | 375-73-5 | Sigma-Aldrich |

### Preparative Examples of Fluorinated Coupling Agents

### Preparative Example 1

To a 500 ml round-bottom flask equipped with a stir-bar and septum under nitrogen was added 120 g (0.0663 mole, 1810 number average molecular weight (Mₙ) of HFPO Oligomer Diacrylate and 120 g of 1,1,1-trifluorotoluene which was previously dried as a 50% solids solution over 4-Angstrom molecular sieves in a septum capped bottle. Next, 1.42 g (1.46 ml, 00.007366 mole, Mₙ= 193.32 g/mole} N-methyl-3-aminopropyltrimethoxysilane was added and the reactants were stirred at room temperature (RT) for 2 hrs, at which time an aliquot was evaluated by ¹H Fourier transform nuclear magnetic resonance spectroscopy (FT-NMR) in D8-tetrahydrofuran/Freon® 113. The reaction was then concentrated on a rotary evaporator at 2 torr at 57° C. for about 30 min and bottled under nitrogen. The structure for Preparative Example 1 is as follows:

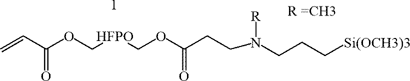

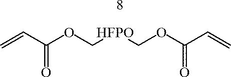

### Preparative Example 1-2 to 1-8

Reactions were run in a manner similar to that for Preparative Example 1, except that reactions run in Novec® 7200 were concentrated at about 35° C. under water aspirator vacuum for about 15 min, then at about 2 torr for 30 min. For Examples 1-2 to 1-8 different amounts of the same reactants were used as detailed in the following Table 2.

TABLE 2

Compositional Details for Preparative Examples 1-2 to 1-8

| Sample number | Amount of HFPO diacrylate | | Silane | Amount of SilaneSilane | | Solvent | Amount of Solvent | Approximate Molar Ratio of HFPO diacrylate to Silane |
|---|---|---|---|---|---|---|---|---|
| | (g) | (mole) | | (g) | (mole) | | (g) | |
| Preparative Example 1-2 | 27.36 | 0.01511 | N-Me-APTMS | 0.731 | 0.003779 | TFT | 27.36 | 4 to 1 |
| E Preparative xample 1-3 | 26.68 | 0.01474 | N-Me-APTMS | 1.068 | 0.005527 | TFT | 26.68 | 2.66 to 1 |
| Preparative Example 1-4 | 23.32 | 0.01454 | N-Me-APTMS | 1.406 | 0.00727 | TFT | 26.32 | 2 to 1 |
| Preparative Example 1-5 | 40.00 | 0.02209 | N-Me-APTMS | 0.475 | 0.002455 | Novec® 7200 | 40.00 | 9 to 1 |
| Preparative Example 1-6 | 30.00 | 0.01657 | N-Me-APTMS | 0.712 | 0.003683 | TFT | 30.00 | 9 to 2 |
| Preparative Example 1-7 | 26.68 | 0.01474 | N-Me-APTMS | 1.0684 | 0.00553 | TFT | 26.68 | 9 to 3.38 |
| Preparative Example 1-8 | 26.32 | 0.01454 | N-Me-APTMS | 1.4056 | 0.00727 | TFT | 26.32 | 9 to 4.5 |

### Preparative Example 2

Reactions were run in a manner similar to that for Preparative Example 1, , using 30.00 g (0.01657 mole, Mₙ = 1810 g/mole) of HFPO Oligomer Diacrylate except that 0.362 g (0.001842 mole) of 3-mercaptopropyl)trimethoxysilane (MPTMS) and 0.44 g of 10% by weight Hunig’s base in TFT (0.044 g solids) was used in place of the N-Me-APTMS. The structure for Preparative Example 2 is as follows:

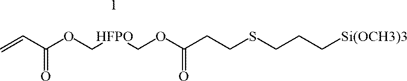

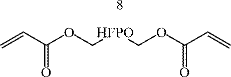

### Preparative Examples 2-2 to 2-3

Reactions were run in a manner similar to that for Preparative Example 2, except that reactions run in Novec® 7200 were concentrated at about 35° C. under water aspirator vacuum for about 15 min, then at about 2 torr for 30 min. For Examples 2-2 to 2-3 different amounts of the same reactants were used as detailed in the following Table 3.

TABLE 3

Compositional Details for Preparative Examples 2-2 to 2-3

| | Amount of HFPO diacrylate | | Silane | Amount of Silane | | Solvent | Amount of Solvent | Amount of Hunig’s Base | Approximate Molar Ratio HFPO diacrylate to Silane |
|---|---|---|---|---|---|---|---|---|---|
| Sample number | (g) | (mole) | | (g) | (mole) | | (g) | (g) | |
| Example 2-2 | 65.00 | 0.03591 | MPTMS | 0.783 | 0.00399 | TFT | 65.00 | 0.026 | 9 to 1 |
| Example 2-3 | 33.18 | 0.01833 | MPTMS | 0.800 | 0.00407 | TFT | 33.18 | 0.026 | 9 to 2 |

### Preparative Example 3

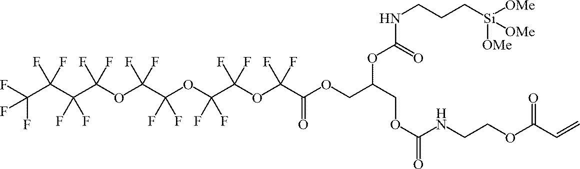 [SMILES: C=CC(=O)OCCNC(=O)OCC(COC(=O)C(F)(F)OC(F)(F)C(F)(F)OC(F)(F)C(F)(F)OC(F)(F)C(F)(F)C(F)(F)C(F)(F)F)OC(=O)NCCC[Si](OC)(OC)OC]

### Preparative Example 3A

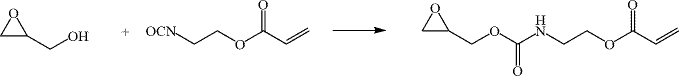

A clean, dry glass jar was charged with magnetic stir-bar, 9.95 g (70.6 millimoles) IEA, and 2 drops DBTDL. Keeping exotherm under 60° C., 5.23 g (70.6 millimoles) glycidol was added portion-wise in approximately 1 ml increments with stirring. The reaction mixture was stirred under ambient atmosphere until complete by ATR-IR (loss of the isocyanate peak around 2270 cm⁻¹). Glycidol IEA urethane product was obtained in quantitative yield as a clear, colorless, pourable-viscosity oil. The reaction product was confirmed using H-NMR.

### Preparative Example 3B

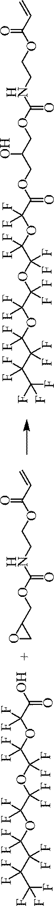

A clean, dry glass jar was charged with magnetic stir-bar and 3.85 g (17.9 millimoles) Glycidol IEA described immediately above. Keeping the exotherm under 50° C., 10.04 g (17.9 millimoles) PFTDA was added portion-wise in approximately 1 ml increments with stirring. The reaction mixture was stirred under ambient atmosphere until complete using H-NMR (shift of the epoxy proton peaks to ether and alcohol proton peaks). Perfluoro Glycidol IEA urethane alcohol product was obtained in quantitative yield as a clear, colorless, pourable-viscosity oil. The reaction product was confirmed using H-NMR.

The following reaction scheme was followed to make Preparative Example 3:

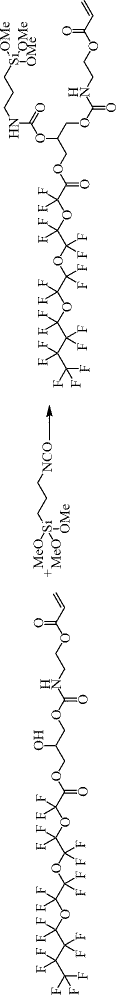

A clean, dry glass jar was charged with magnetic stir-bar, 10.26 g (13.2 millimoles) perfluoro Glycidol IEA (Example 2), and 2 drops TEA. Keeping the exotherm under 40° C., 2.71 g (13.2 millimoles) 3-isocyanatopropyltrimethoxysilane was added portion-wise in approximately 1 ml increments with stirring. The reaction mixture was stirred under a dry ambient atmosphere until complete by ATR-IR (loss of the isocyanate peak around 2270 cm⁻¹). Perfluoro Glycidol IEA Trimethoxysilane product was obtained in quantitative yield as a clear, colorless, pourable-viscosity oil. The reaction product was confirmed using H-NMR.

### Preparative Example 4

### Preparative Example 4A

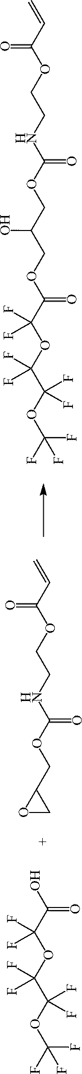

A clean, dry glass jar was charged with magnetic stir-bar and 3.63 g (16.9 millimoles) Glycidol IEA (Preparative Example 3A). Keeping the exotherm under 50° C., 5.00 g (17.9 millimoles) PFDHA was added portion-wise in approximately 1 ml increments with stirring. The reaction mixture was stirred under ambient atmosphere until complete using H-NMR (shift of the epoxy proton peaks to ether and alcohol proton peaks). Perfluoro Glycidol IEA urethane alcohol product was obtained in quantitative yield as a clear, colorless, pourable-viscosity oil. The reaction product was confirmed using H-NMR.

### Preparative Example 4B

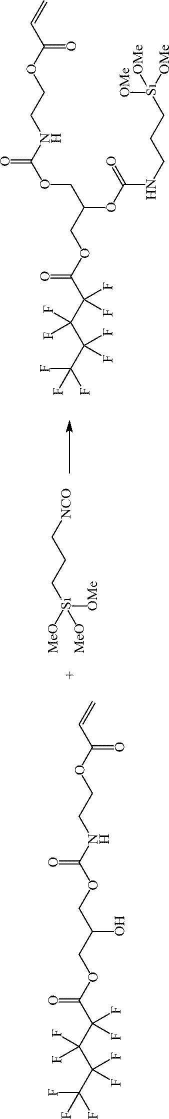

A clean, dry glass jar was charged with magnetic stir-bar, 10.0 g (12.9 millimoles) perfluoro Glycidol IEA (Preparative Example 4A), and 2 drops TEA. Keeping the exotherm under 40° C., 2.64 g (12.9 millimoles) 3-isocyanatopropyltrimethoxysilane was added portion-wise in approximately 1 ml increments with stirring. The reaction mixture was stirred under a dry ambient atmosphere until complete by ATR-IR (loss of the isocyanate peak around 2270 cm⁻¹). Perfluoro Glycidol IEA Trimethoxysilane product was obtained in quantitative yield as a clear, colorless, pourable-viscosity oil. The reaction product was confirmed using H-NMR.

### Preparative Example 5

To a 500 ml flask equipped with a stir-bar was charged HFPO methyl ester 150.00 g, (0.119237 mole, Mₙ = 1258 g/mole) and AEAPTMS 26.51 g (0.119237 moles, Mₙ = 222.36 g/mole), and the reaction mixture was stirred over 2.5 days at room temperature. An aliquot was analyzed by Fourier transform infrared spectroscopy (FTIR), which showed disappearance of the ester doublet at about 1800 and 1780 cm⁻¹ (small, large) and appearance of an amide band at about 1718 cm⁻¹. The reaction was concentrated at about 3 torr for 40 min at 55° C. to provide 312.26 g of a clear liquid oil of the HFPO—C(O)NH—CH₂CH₂ _{N}H—CH₂CH₂CH₂—Si(OCH₃)₃ intermediate.

To a 100 ml flask equipped with a stir-bar was charged IEA 1.95 g (0.013799 mole), and the flask was placed in an ice bath under dry air. Next, 20.00 g (0.133916 mole, Mn = 1449.36 g/mole) of HFPO—C(O)NH—CH₂CH₂ _{N}H—CH₂CH₂CH₂—Si(OCH₃)₃ (was added via a pressure equalizing funnel. At about 27 min, 36.3 g of THF was added to the reaction vessel. At this point about one-third of the silane was added. At about 1.5 hrs all the silane was added to the flask and the funnel was rinsed with a few grams of THF into the reaction. Analysis by FTIR of an aliquot showed no —NCO peak at 2265 cm⁻¹. The material was concentrated on a rotary evaporator at up to 70° C. and about 3 torr to provide 21.59 g of a clear liquid. The structure for Preparative Example 5 is as follows:

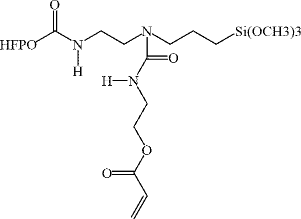

### Preparative Example 6

A 1 L round bottom flask equipped with overhead stirrer was charged with G-AC-MAC 100.00 g (0.46681 mole), TEA 49.60 g (0.049015 mole), and 302 g of dichloromethane, and placed in an ice bath under dry air. Via a pressure equalizing funnel, TMS chloride was added over about 45 min, and was allowed to stir overnight, warming to room temperature. Next, 400 g of water was added to the reaction and stirred. A small aliquot was washed, dried over anhydrous magnesium sulfate, filtered, concentrated and analyzed by ¹H FTNMR, showing the reaction to be complete. This aliquot was diluted with dichloromethane and added to the rest of the reaction, the layer separated, dried over anhydrous magnesium sulfate, and concentrated on a rotary evaporator to provide a clear oil. The structure of this intermediate is as follows:

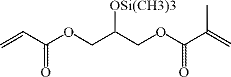

A small vial with a stir-bar was charged with 21.8 g (0.015041 mole, Mₙ = 1449.36 g/mole) HFPO-C(O)NH-CH₂CH₂ _{N}H-CH₂CH₂CH₂-Si(OCH₃)₃ and 3.95 g (0.013793 mole, Mₙ = 286.37 g/mole) of the silane diacrylate intermediate just described and stirred for 24 hrs in a 60° C. water bath, after which time an aliquot was analyzed by ¹H FTNMR, and its spectra was found to be consistent with the desired structure. The structure of Preparative Example 6 is as follows:

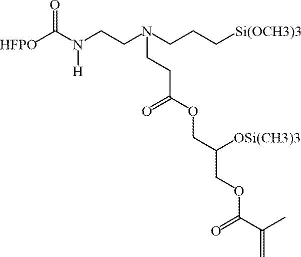

### Preparative Example 7

Reactions were run in a manner similar to that for Preparative Example 1, except that Bis-(propyltrimethoxysilyl) amine (B-PTMS) was used in place of the N-Me-APTMS, and the reactions was run in Novec® 7200 and concentrated at about 35° C. under water aspirator vacuum for about 15 min, then at about 2 torr for 30 min. The structure for Preparative Example 7 is as follows:

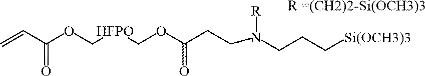

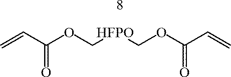

### Preparative Example 8

Preparative Example 8 was synthesized in a sequential one-pot two-step reaction. A clean, dry glass jar was charged with magnetic stir-bar, 2.53 g (17.79 millimoles) GMA, and 2 drops TEA. Keeping the exotherm under 60° C., 10.00 g (17.79 millimoles) PFTDA was added portion-wise in approximately 1 ml increments with stirring. The reaction mixture was stirred under ambient atmosphere until complete using H-NMR (shift of epoxy proton peaks to ether and alcohol proton peaks).

To the same reaction mixture was added 2 drops TEA and 2 drops DBTDL, followed by portion-wise addition of 4.40 g (17.79 millimoles) 3-isocyanatopropyltriethoxysilane at a rate appropriate to maintain exotherm under 60° C. (about 1 ml portions). The reaction mixture was stirred under a dry ambient atmosphere until complete by ATR-IR (loss of the isocyanate peak around 2270 cm⁻¹). Perfluoro GMA Triethoxysilane product was obtained in quantitative yield as a clear, colorless, pourable-viscosity oil. The reaction product was confirmed using H-NMR. The structure for Preparative Example 8 is as follows:

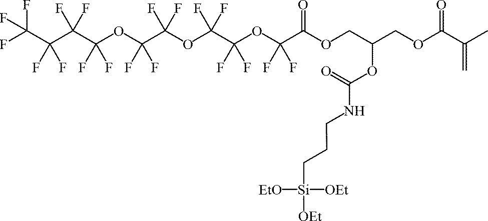 [SMILES: C=C(C)C(=O)OCC(COC(=O)C(F)(F)OC(F)(F)C(F)(F)OC(F)(F)C(F)(F)OC(F)(F)C(F)(F)C(F)(F)C(F)(F)F)OC(=O)NCCC[Si](OCC)(OCC)OCC]

### Preparative Example 9

HFPO—C(O)NH—CH₂CH₂ _{N}H—CH₂CH₂CH₂—Si(OCH₃)₃ was reprepared in a fashion similar to the preparation of HFPO—C(O)NH—CH₂CH₂ _{N}H—CH₂CH₂CH₂—Si(OCH₃)₃ intermediate from Preparative Example 4, 100.00 g (0.0840 mole, Mₙ = 1190 g/mole or nominally Mₙ = 1321 g/mole) of HFPO methyl ester and 18.69 g (0.0840 mole, Mₙ = 222.36 g/mole) of AEAPTMS.

Next 22.44 g (0.01864 mole, Mₙ = 1203.9 g/mole) of HFPO—C(O)NH—CH₂CH_{2N}H—CH₂CH₂CH₂—Si(OCH₃)₃ was dissolved in about 30 ml of TFT in a pressure equalizing addition funnel. Then 4.46 g (0.01864 mole, Mₙ = 239.22 g/mole) was dissolved in TFT to provide a volume equal to that of the HFPO—C(O)NH—CH₂CH₂ _{N}H—CH₂CH₂CH₂—Si(OCH₃)₃ dissolved in TFT. About 22 g of TFT was charged into a 250 ml three-necked round-bottom flask equipped with an overhead stirrer, and the pressure equalizing funnels with the HFPO—C(O)NH—CH₂CH₂ _{N}H—CH₂CH₂CH₂—Si(OCH₃)₃ and BEI were placed in the other two necks of the flask under dry air.

The flask was placed in a methanol-water-dry ice bath maintained at -10 to -20° C. The HFPO—C(O)NH—CH₂CH₂ _{N}H—CH₂CH₂CH₂—Si(OCH₃)₃ and BEI and TFT solutions were added over about 2 hrs at equal volume (and thus equimolar) rates. The cooling bath was removed and the flask was allowed to warm up to 20° C. Using overhead stirring, the material was stripped at up to 55° C. (in a 75° C. bath) at a vacuum as low as 2.4 torr over 40 min. Proton NMR analysis indicated that about 11% by mole of the BEI was remaining. FTIR analysis also showed an —NCO peak at about 2265 cm⁻¹.

Next 23.09 g of the resultant product was added into a 250 ml three-necked round-bottom flask equipped with an overhead stirrer under dry air. To a pressure equalizing addition funnel was added 2.55 g of HFPO—C(O)NH—CH₂CH_{2N}H—CH₂CH₂CH₂—Si(OCH₃)₃ and about 9 g of TFT. The flask was placed in a methanol-water-dry ice bath maintained at -10 to-20° C., and the solution of HFPO—C(O)NH—CH₂CH₂ _{N}H—CH₂CH₂CH₂—Si(OCH₃)₃ in TFT was added over about 9 min, after which time it was removed from the cooling bath. NMR and FTIR analyses showed respectively much less or no —NCO left. The reaction product was stripped as before, providing the product. The structure for Preparative Example 9 is as follows:

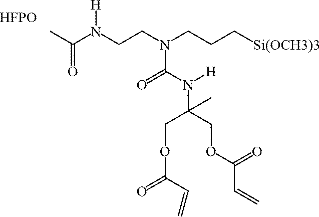

### Preparative Example 10

A 500 ml single-necked round-bottom flask equipped with a stir-bar was charged with 100 g (0.0757 eq, Mₙ = 1321 g/moles) of HFPO methyl ester (HFPO—C(O)CH₃) and 9.95 g Serinol (0.109209 mole, Mₙ = 91.11 g/mole), and heated in an oil bath at 40° C. for 45 min with stirring, and then at 75° C. for 3.25 hrs more. FTIR analysis showed a strong peak at 1790 cm⁻¹ corresponding to the methyl ester, and some amide peak corresponding to the desired product at 1714 cm⁻¹.

The flask was placed on a rotary evaporator at 75° C. at 22 torr for 34 min. A sample taken for FTIR analysis showed the equal intensity of peaks at 1790 cm⁻¹ and 1714 cm⁻¹. The reaction was monitored by FTIR at 1.5 hrs and 2.25 hrs at 22 torr and monitoring by FTIR was continued for each step.

Next the pressure was reduced to 4 torr for 1.25 hrs (3.5 hrs total time) on the rotary evaporator. Next 1 g of Serinol was added and stripping on the rotary evaporator continued for an additional 2.25 hrs; still a small peak remained at 1790 cm⁻¹. Then 1.36 g more Serinol was added and stripping was continued for 2.75 hrs more at 4 torr, and at the end of that time no methyl eater peak remained. The material was dissolved in 200 g of MTBE, successively washed with 20 g of 2 N HCl in a separatory funnel, 20 g of 10% sodium bicarbonate, and finally with 20 g water and 10 g of a brine solution, allowing the lower aqueous phase to separate from the upper organic phase in each case.

The organic phase was dried over anhydrous magnesium sulfate, filtered, washing the filtrate with additional MTBE. The material was stripped under water aspirator vacuum on a rotary evaporator for 2.5 hrs. This intermediate, which was characterized by ¹H FT-NMR has the structure:

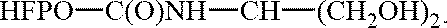

A 250 ml flask eqipped with overhead stirrer was charged with 40.0 g (0.0576 equivalents, 694.06 equivalent weight) HFPO—C(O)NH—CH—(CH₂OH)₂, 8.16 g (0.0807 equivalents, 101.19 equivalent weight) triethylamine, and 80 g MTBE and placed under a dry air atmosphere. The reactants were heated to 38° C., and 6.78 g (0.07492 equivalents, Mₙ = 90.51 g/moles) acryloyol chloride was added via a pressure equalizing additon funnel over about 30 min. After reacting for about 22 hrs, the reaction had lost much of its solvent, and MTBE was added to bring the reaction to its initial weight of all charges.

The reactants were stirred with 26.6 g of 1 N HCl, and allowed to separate into layers in a separatory funnel. The phase split was poor, so 21 g of MTBE was added, the contents shaken for 1 min, and the upper organic phase drained back intothe flask. It was stirred for 10 min with 100 g of 10% sodium carbonate, allowed to separate in the separatory funnel, and the upper oragnic phase was drained back into the flask and stirred for 10 min with 33.3 g brine and 73.8 g water. The upper organic phase was dried over anhydrous magnesium sulfate, and filtered, the filtrate being washed with additonal MTBE. The solution was treated with 0.016 g BHT and 0.004 g TEMPO, concentrated ona rotary evaporator at 45° C. at 22 torr for 30 min, foaming a fair amount, and then concentrated for 30 min at 0.85 torr and 63° C. to yield 36.27 g of product that was charcaterized by ¹H FT-NMR. This intermediate, which was characterized by ¹H FT-NMR, has the structure:

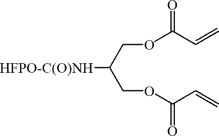

The 36.27 g of product was diluted to 40% solids with 54.41 g THF, then stored over 4-Angstrom Molecular Sieves. Next 88.57 g of the 40% solution (33.43 g solids, 0.02205 mole, Mₙ = 1516 g/mole) was charged through a 0.45 micron PTFE syringe filter into a 250 ml round-bottom flask equipped with a stir-bar along with 0.947 g (0.0490 mole, Mₙ = 193.32 g/moles) APTMS, a 9:2 ratio of the HFPO adduct to the aminosilane. The reactants were stirred for 2 hrs at room temperature, then concentrated at 35° C. for 20 min on a rotary evaporator at 0.75 torr. The structure which was characterized by ¹H FT-NMR for Preparative Example 10 is as follows:

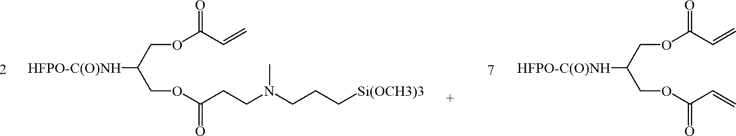

### Preparative Example 11

A 100 ml single-necked round-bottom flask equipped with a stir-bar was charged with 39.23 g (0.060216 equivalents, equivalent weight = 651.49) of HFPO di(methyl ester) alpha, omega and 3.68 g of 2-aminoethanol (0.602 mole, 61.08 EW), and stirred for 45 min at room temperature. FTIR analysis showed a small peak at 1790 cm⁻¹ corresponding to the methyl ester, and a larger amide peak corresponding to the desired product at 1710 cm⁻¹.

The flask was placed in an oil bath heated to 75C for 1.5 h and FTIR analysis showed no methyl ester peak, only the product amide peak. The reaction was placed on a rotary evaporator and stripped at 65° C. for 1 hr and 45 min under a vacuum of 0.7 torr. The structure for this intermediate which was characterized by ¹H FT-NMR is as follows:

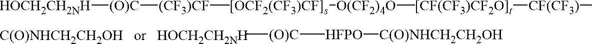

A 250 ml flask eqipped with an overhead stirrer was charged with 30.0 g (0.044086 equivalents; 680.49 equivalent weight) HOCH₂CH₂ _{N}H—(O)C—HFPO—C(O)NHCH₂CH₂OH, 6.25 g (0.06172 mole, 101.19 equivalent weight) triethylamine, and 60 g MTBE and placed under a dry air atmosphere. The reactants were heated to 38° C., and 4.99 g (0.0551 equivalents, Mₙ = 90.51 g/mole) acryloyol chloride was added via a pressure equalizing addition funnel over about 20 min. After reacting for about 22 hrs,. the reaction had lost some of its solvent, and MTBE was added to bring the reaction to its initial weight of all charges. The reactants were stirred for 10 min with 18 g of 1 N HCl and 36 g water, but there was no split apparrent.

To obtain a split, the reaction was succesively shaken in the separatory funnel with treated with 10 g of brine, 23 g of MTBE, 10 g of brine, and 10 g of brine which produced a split over 1.5 hrs. The bottom aqueous layer weighed 48.3 g and the top organic layer weighed 151.05 g. A 1 g aliquot of the top organic layer was placed in a vial and shaken with 0.75 g of 10% aqueous sodium carbonate, producing a good phase split. This was added to the top organic layer, which was then stirred for 10 min with 100 g of 10% aqueous sodium carbonate, and allowed to phase separate in a separatory funnel overnight. The bottom aqueous layer was 139.83 g and the top organic layer was 109.43 g.

The top organic phase was stirred with 54 g of brine for 11 min and separated into a bottom aqueous layer of 55.37 g and a top organic layer of 96.69 g. The organic layer was dried over anhydrous magnesium sulfate and filtered through a C porosity fritted Buchner funnel with additonal MTBE. About 2.5 mg of TEMPO and 10 mg of BHT was added, and the material was concentrated on a rotary evaporator at 44° C. at 50-250 torr of vacuum to remove most of the solvent, then at 63° C. at 0.85 torr for 30 min, yielding 31.22 g of a slightly cloudy yellow-brown oil. The material was diluted to 40% solids in THF, and dried over 4-Angstrom Molecular Sieves. The structure for this intermediate which was characterized by ¹H FT-NMR is as follows:

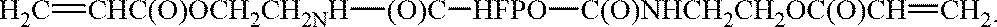

Next 72.76 g of the 40% solids THF solution (29.10 g solids, 0.0198 mole, Mₙ = 1469 g/mole) H₂C═CHC(O)OCH₂CH₂ _{N}H—(O)C—HFPO—C(O)NHCH₂CH₂OC(O)CH═CH₂ was charged through a 0.45-micron PT FE syringe filter into a 250 ml round-bottom flask equipped with a stir-bar along with 0.85 g (0.0044 mole, Mₙ = 93.32 g/mole) APTMS, a 9:2 molar ratio of the HFPO adduct to the aminosilane.

The reactants were stirred for 2 hrs at room temperature, then concentrated at 35° C. for 20 min on a rotary evaporator at 0.75 torr. The structure which was characterized by ¹H FT-NMR for Preparative Example 11 is as follows:

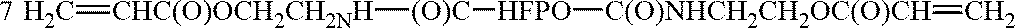

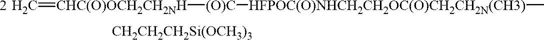

### Preparative Example 12

A weight of 50.28 g of 40% solids TFT solution dried over 4-Angstrom Molecular Sieves (20.11 g solids, 0.01369 mole, Mₙ = 1469 g/mole) H₂C═CHC(O)OCH₂CH₂ _{N}H—(O)C—HFPO—C(O)NHCH₂CH₂OC(O)CH═CH₂ was charged through a 0.45-micron PTFE syringe filter into a 250 ml round-bottom flask equipped with a stir-bar along with 0.60 g (0.003042 mole, Mₙ= 193.32 g/mole) MPTMS, a 9:2 molar ratio of the HFPO adduct to the thiosilane, and 0.98 g (0.098 g solids, 0.000761 mole) of a 10% solids solution of Hunig’s base in TFT.

The reactants were stirred for 24 hrs at room temperature, then concentrated at 35° C. for 30 min on a rotary evaporator at 0.85 torr. The structure which was characterized by ¹H FT-NMR for Preparative Example 12 is as follows:

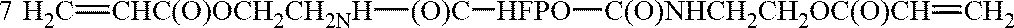

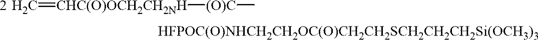

### Film Deposition Examples

### Comparative Example 1

HFPO oligomer diacrylate was deposited onto a polyethylene terephthalate (PET) substrate film by an organic vapor deposition process similar to that described in 6,045,864 (Lyons et al.). The HFPO oligomer diacrylate was delivered separate to and blended with Darocur 1173 photoinitiator immediately prior to vaporization. The layer was deposited as follows:

A roll of 0.127 mm thick PET film (commercially available from DuPont, ST505) was loaded into a roll-to-roll vacuum processing chamber, and the chamber was pumped down to a pressure of less than 10 mtorr. A section of this roll was previously sputter-coated with a 25 nm layer of silicon aluminum oxide.

Prior to deposition, the HFPO diacrylate and Darocur 1173 materials were separately degassed under vacuum to a pressure of less than 100 mtorr and loaded into two separate stainless-steel syringes. Nitrogen was introduced into the chamber to maintain a pressure of about 200 mtorr.

Prior to deposition, the film surface was treated with a nitrogen plasma at a power of 100 W (Ti cathode). The film was translated through the chamber at a web speed of 12.5 fpm, and the HFPO diacrylate solution was then deposited on the film surface while the backside surface of the film was in contact with a backing roll cooled to 0° C. The HFPO diacrylate solution was pumped at a flow rate of 2.00 ml/min, and the Darocur 1173 was pumped at a flow rate of 0.05 ml/min, and the two liquid streams were blended together immediately prior to entry into an ultrasonic atomizer, and delivered through an ultrasonic atomizer into an evaporation chamber heated to 250° C. The diacrylate vapor was condensed onto the film surface and exposed to UVC lamps (6) (Heraeus mercury-amalgam low pressure, approximately 55 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 1161 nm. The deposited coating was characterized with a BYK Gardner haze-gard PLUS to have an average transmission (visible) = 96.0 ± 0.2% and Haze = 1.22 ± 0.08. The adhesion of the deposited coating was characterized with tape peel testing, with the results in Table 4: below. The adhesion performance is poor without any coupling agent as expected, with complete removal of the coating with both 3 M 600 and 610 tape cross-hatch peel tests.

### Comparative Example 2

HFPO oligomer diacrylate deposited onto a polyethylene terephthalate (PET) substrate film by an organic vapor deposition process similar to that described in 6,045,864 (Lyons et al.). The HFPO oligomer diacrylate was blended with nonfluorinated coupling agent K90 (5.0%) and (1.0%) photoinitiator corresponding to Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference.

During combination and mixing of the solution, it was noted that the solution turned hazy (opaque) and milky-white, likely due to the immiscibility of the K90 material in the HFPO diacrylate.

The layer was deposited as follows:

A roll of 0.127 mm thick PET film (commercially available from DuPont, ST505) previously sputter-coated with a 25 nm layer of silicon aluminum oxidewas loaded into a roll-to-roll vacuum processing chamber, and the chamber was pumped down to a pressure of less than 10 mtorr.

Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr.

Prior to deposition, the film surface was treated with a nitrogen DC magnetron plasma at a power of 100 W (Ti cathode). The film was translated through the chamber at a web speed of 6.0 fpm, and the HFPO diacrylate solution was then deposited on the film surface while the backside surface of the film was in contact with a backing roll cooled to 0° C.

The HFPO diacrylate solution was pumped at a flow rate of 1.05 ml/min through an ultrasonic atomizer into an evaporation chamber heated to 250° C.

The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C.

Following deposition, the film was wound onto a core and later removed for sampling. While unwinding the roll for sampling, it was noted there were two separate sections of the sample. The deposited layer started as a relatively clear coating, which continued for the majority of the sample length (approximately 30 FT, subsequently referred to as Comparative Example 2 Section A). At the end of the sample, defined as the position on the web where the last amount of HFPO diacrylate solution was discharged from the syringe, the deposited layer was observed to be significantly more hazy than the sample deposited earlier – this section was approximately two to three feet in length (subsequently referred to as Comparative Example 2 Section C).

This is thought to be a result of phase separation of the K90 material and HFPO diacrylate in the syringe, causing a separate fraction of solution enriched in K90 to be delivered to the evaporator at the end of the sample. The larger amount of K90 in the vapor phase is then thought to have condensed on the web with residual HFPO diacrylate and phase-separated, resulting in the hazy coating observed. This observation highlights the processing challenges using immiscible coupling agents, as it is not possible to deliver a homogenous solution with stability over time.

The deposited coating (Comparative Example 2 Section A) was characterized by spectroscopic ellipsometry (JA Woollam alpha-SE) using a Cauchy dispersion model to have a thickness (center of web) = 1228 nm. The different sections (A and C) were characterized for average optical transmission (visible) and Haze with a BYK Gardner haze-gard PLUS:
Comparative Example 2 Section A: AVG %T = 93.4 ± 0.1, Haze = 2.52 ± 0.01
Comparative Example 2 Section C: AVG %T = 93.6 ± 0.3, Haze = 8.2 ± 0.1

The increased haze relative to Comparative Example 1 is thought to be a result of phase separation of the immiscible component (K90) in the deposited coating and would be unacceptable in many applications. The adhesion of the deposited coating was characterized with tape peel testing, with the results in Table 4: below. The cross-hatch tape peel adhesion results show relatively little adhesion improvement relative to Comparative Example 1. The adhesion results together with the increased haze demonstrate the need for development of new coupling agent materials, which are given in the following examples.

### Example 1

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 1 (90%) and photoinitiator A4YJ5ZZ.02-238-2 (1.0%). The layer was deposited as follows: A roll of 0.127 mm thick PET film (commercially available from DuPont, ST505) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.05 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 1130 nm. The deposited coating was characterized with a BYK Gardner haze-gard PLUS to have an average optical transmission (visible) = 93.5 ± 0.1% and Haze = 1.34 ± 0.09. The adhesion of the deposited coating was characterized with tape peel testing, with the results in Table 4: below. The adhesion results with the addition of Preparative Example 1demonstrate substantial adhesion improvement compared with Comparative Examples 1 and 2, and furthermore there was no significant difference in the haze or refractive index of the deposited layer.

### Example 2

HFPO oligomer diacrylate was deposited onto a polyethylene terephthalate (PET) substrate film by an organic vapor deposition process similar to that described in 6,045,864 (Lyons et al.). The HFPO oligomer diacrylate was blended with Preparative Example 2 and this solution was delivered separate to and blended with Darocur 1173 photoinitiator immediately prior to vaporization.

The layer was deposited as follows: A roll of 0.127 mm thick PET film (commercially available from DuPont, ST505) previously sputter-coated with a 25-nm layer of silicon aluminum oxide was loaded into a roll-to-roll vacuum processing chamber, and the chamber was pumped down to a pressure of less than 10 mtorr.

Prior to deposition, the HFPO diacrylate solution and Darocur 1173 materials were separately degassed under vacuum to a pressure of less than 100 mtorr and loaded into two separate stainless-steel syringes. Nitrogen was introduced into the chamber to maintain a pressure of about 200 mtorr. Prior to deposition, the film surface was treated with a nitrogen plasma at a power of 100 W (Ti cathode).

The film was translated through the chamber at a web speed of 12.5 fpm, and the HFPO diacrylate solution was then deposited on the film surface while the backside surface of the film was in contact with a backing roll cooled to 0° C. The HFPO diacrylate solution was pumped at a flow rate of 2.00 ml/min, and the Darocur 1173 was pumped at a flow rate of 0.05 ml/min, and the two liquid streams were blended together immediately prior to entry into an ultrasonic atomizer, and delivered through an ultrasonic atomizer into an evaporation chamber heated to 250° C.

The vapor was condensed onto the film surface and exposed to UVC lamps (6) (Heraeus mercury-amalgam low pressure, approximately 55 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The adhesion of the deposited coating was characterized with tape peel testing, with the results in Table 4: below. The adhesion results demonstrate substantial adhesion improvement relative to the Comparative Examples 1 and 2.

### Example 3

HFPO oligomer diacrylate was deposited onto a polyethylene terephthalate (PET) substrate film by an organic vapor deposition process similar to that described in 6,045,864 (Lyons et al.). The HFPO oligomer diacrylate was blended with Preparative Example 3(5%) and (1%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference.

The layer was deposited as follows: A roll of 0.127 mm thick PET film (commercially available from DuPont, ST505) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe.

Nitrogen was introduced into the chamber to maintain a pressure of about 150 mtorr. Prior to deposition, the film surface was treated with a nitrogen DC magnetron plasma at a power of 100 W (Ti cathode). The film was translated through the chamber at a web speed of 6.0 fpm, and the HFPO diacrylate solution was then deposited on the film surface while the backside surface of the film was in contact with a backing roll cooled to 0° C.

The HFPO diacrylate solution was pumped at a flow rate of 1.10 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 1072 nm and a refractive index = 1.35 (550 nm). The deposited coating was characterized with a BYK Gardner haze-gard PLUS to have an average optical transmission (visible) = 93.4 ± 0.1% and Haze = 1.32 ± 0.03. The adhesion of the deposited coating was characterized with tape peel testing, with the results in Table 4: below. The adhesion results demonstrate adhesion improvement with the addition of Preparative Example 3 relative to Comparative Examples 1 and 2, and furthermore there was no significant difference in the haze or refractive index.

### Example 4

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 4 (10%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. The layer was deposited as follows: A roll of 0.127 mm thick PET film (commercially available from DuPont, ST504) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.00 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 679 nm, indicating that this Preparative Example 4 decreased the process efficiency (lower than target thickness). The deposited coating was characterized with a BYK Gardner haze-gard PLUS to have an average optical transmission (visible) = 93.0 ± 0.1% and Haze = 1.49 ± 0.04. The adhesion of the deposited coating was characterized with tape peel testing, with the results in Table 4: below. The adhesion results with the addition of Preparative Example 4 demonstrate substantial adhesion improvement compared with Comparative Examples 1 and 2, and furthermore there was no significant difference in the haze or refractive index of the deposited layer.

### Example 5

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 1-6 (45%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. The layer was deposited as follows: A roll of 0.127 mm thick PET film (commercially available from DuPont, ST504) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.00 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 965 nm. The deposited coating was characterized with a BYK Gardner haze-gard PLUS to have an average optical transmission (visible) = 93.0 ± 0.1% and Haze = 0.78 ± 0.05. The adhesion of the deposited coating was characterized with tape peel testing, with the results in Table 4: below. The adhesion results with the addition of Preparative Example 1-6 demonstrate substantial adhesion improvement compared with Comparative Examples 1 and 2, and furthermore there was no significant difference in the haze or refractive index of the deposited layer.

### Example 6

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 2 (90%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. The layer was deposited as follows:

A roll of 0.127 mm thick PET film (commercially available from DuPont, ST504) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.00 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 1015 nm. The deposited coating was characterized with a BYK Gardner haze-gard PLUS to have an average optical transmission (visible) = 93.1 ± 0.1% and Haze = 0.79 ± 0.04. The adhesion of the deposited coating was characterized with tape peel testing, with the results in Table 4: below. The adhesion results with the addition of Preparative Example 2 demonstrate substantial adhesion improvement compared with Comparative Examples 1 and 2, and furthermore there was no significant difference in the haze or refractive index of the deposited layer.

### Example 7

HFPO oligomer diacrylate deposited onto a polyethylene terephthalate (PET) substrate film by spin-coating out of solution.

The HFPO oligomer diacrylate was blended with Preparative Example 2-3 (46%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. This solution was then diluted with Novec® 7200 solvent, and immediately prior to spin-coating a solution of nonafluorobutane-1-sulfonic acid in Novec® 7200 solvent (2.0%) was added to the mixture at a concentration of 2.0% nonafluorobutane-1-sulfonic acid with respect to the total solids to yield a solution of about 20% solids. The layer was deposited as follows:

0.127 mm thick PET film (commercially available from DuPont, ST504) previously sputter-coated with a 25-nm layer of silicon aluminum oxide was affixed to a rigid silicon wafer (carrier), centered on the vacuum chuck of the spin-coater (Weinview SC 100-SE), and suctioned to the chuck by pulling vacuum. Approximately 2 ml of the HFPO diacrylate solution was dispensed onto the film surface, and the spin-coating was started according to the following profile: accelerating the substrate at 500 rpm/sec (6 seconds), rotating the substrate at 3000 rpm (9 seconds), and decelerating the substrate at 500 rpm/sec (6 seconds) to form a layer approximately 1100 nm in thickness.

Following spin-coating, the sample was removed from the vacuum chuck and placed in an oven set to 60° C. for 60 seconds. The deposited layer was then placed on a conveyor at a speed of 7 fpm and cured by exposure to UVC lamps (12) (mercury-amalgam low pressure, approximately 54 mJ/cm²) in a nitrogen-purged enclosure. The sample was then removed from the silicon wafer (carrier) for characterization.

The deposited coating was characterized by spectroscopic ellipsometry (JA Woollam alpha-SE) using a Cauchy dispersion model to have a thickness (center of sample) = 1730 nm. The adhesion of the deposited coating was characterized with tape peel testing, with the results in Table 4: below. The adhesion results with the addition of Preparative Example 2-3 demonstrate substantial adhesion improvement compared with Comparative Examples 1 and 2.

### Example 8

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 9 (5%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. The layer was deposited as follows: A roll of 0.127 mm thick PET film (commercially available from DuPont, ST504) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.00 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 1015 nm. The deposited coating was characterized with a BYK Gardner haze-gard PLUS to have an average optical transmission (visible) = 93.2 ± 0.1% and Haze = 0.78 ± 0.03. The adhesion of the deposited coating was characterized with tape peel testing, with the results in Table 4 below. The adhesion results with the addition of Preparative Example 9 demonstrate limited adhesion improvement (no post-it peel removal) compared with Comparative Examples 1 and 2, and there was no significant difference in the haze of the deposited layer.

### Example 9

HFPO oligomer diacrylate deposited onto a polyethylene terephthalate (PET) substrate film by spin-coating out of solution.

The HFPO oligomer diacrylate was blended with Preparative Example 12 (45%) and (1.4%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. This solution was then diluted with Novec® 7200 solvent, and immediately prior to spin-coating a solution of nonafluorobutane-1-sulfonic acid in Novec® 7200 solvent (2.0%) was added to the mixture at a concentration of 2.1% nonafluorobutane-1-sulfonic acid with respect to the total solids to yield a solution of about 20% solids. The layer was deposited as follows: 0.127 mm thick PET film (commercially available from DuPont, ST504) previously sputter-coated with a 25-nm layer of silicon aluminum oxide was affixed to a rigid silicon wafer (carrier), centered on the vacuum chuck of the spin-coater (Weinview SC100-SE), and suctioned to the chuck by pulling vacuum. Approximately 2 ml of the HFPO diacrylate solution was dispensed onto the film surface, and the spin-coating was started according to the following profile: accelerating the substrate at 500 rpm/sec (6 seconds), rotating the substrate at 3000 rpm (9 seconds), and decelerating the substrate at 500 rpm/sec (6 seconds) to form a layer approximately 1100 nm in thickness. Following spin-coating, the sample was removed from the vacuum chuck and placed in an oven set to 60° C. for 60 seconds. The deposited layer was then placed on a conveyor at a speed of 7 fpm and cured by exposure to UVC lamps (12) (mercury-amalgam low pressure, approximately 54 mJ/cm²) in a nitrogen-purged enclosure. The sample was then removed from the silicon wafer (carrier) for characterization.

The deposited coating was characterized by spectroscopic ellipsometry (JA Woollam alpha-SE) using a Cauchy dispersion model to have a thickness (center of sample) = 1730 nm. The adhesion of the deposited coating was characterized with tape peel testing, with the results in Table 4 below. The adhesion results with the addition of Preparative Example 12 demonstrate substantial adhesion improvement compared with Comparative Examples 1 and 2.

### Example 10

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 10 (45%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. The layer was deposited as follows: A roll of 0.127 mm thick PET film (commercially available from DuPont, ST504) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.05 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 1130 nm. The deposited coating was characterized with a BYK Gardner haze-gard PLUS to have an average optical transmission (visible) = 93.3 ± 0.1% and Haze = 1.04 ± 0.06. The deposited coating was different in appearance in that some inclusions or particles were observed in the coating.

### Example 11

HFPO oligomer diacrylate deposited onto a polyethylene terephthalate (PET) substrate film by an organic vapor deposition process similar to that described in 6,045,864 (Lyons et al.).

The HFPO oligomer diacrylate was blended with Preparative Example 11 (45%) and (1.0%) photoinitiator as described in Example 1 as disclosed in co-pending, co-filed U.S. Pat. Application Attorney Docket No. 83096US002, titled “MULTILAYER OPTICAL FILMS COMPRISING AT LEAST ONE FLUORINATED (CO)POLYMER LAYER MADE USING A FLUORINATED PHOTOINITIATOR, AND METHODS OF MAKING AND USING THE SAME,” the entire disclosure of which is hereby incorporated herein by reference. The layer was deposited as follows: A roll of 0.127 mm thick PET film (commercially available from DuPont, ST504) previously sputter-coated with a 25-nm layer of silicon aluminum oxide was loaded into a roll-to-roll vacuum processing chamber, and the chamber was pumped down to a pressure of less than 10 mtorr. Prior to deposition, the HFPO diacrylate solution was degassed under vacuum to a pressure of less than 100 mtorr and loaded into a stainless-steel syringe. Nitrogen was introduced into the chamber to maintain a pressure of about 200 mtorr. Prior to deposition, the film surface was treated with a nitrogen DC magnetron plasma at a power of 100 W (Ti cathode).

The film was translated through the chamber at a web speed of 6.0 fpm, and the HFPO diacrylate solution was then deposited on the film surface while the backside surface of the film was in contact with a backing roll cooled to 0° C. The HFPO diacrylate solution was pumped at a flow rate of 1.05 ml/min through an ultrasonic atomizer into an evaporation chamber heated to 250° C. The vapor was condensed onto the film surface and exposed to UVC lamps (6) (Heraeus mercury-amalgam low pressure, approximately 115 mJ/cm²) to form a layer approximately 1100 nm in thickness. The UVC germicidal lamps were maintained in a water-cooled housing, and the lamp temperature (indicative of the output) was stabilized between 75-85° C. Following deposition, the film was wound onto a core and later removed for sampling.

The deposited coating was characterized by spectroscopic ellipsometry (JA Woollam alpha-SE) using a Cauchy dispersion model to have a thickness (center of web) = 813 nm, indicating that Preparative Example # decreased the process efficiency (lower than target thickness). The deposited coating was characterized with a BYK Gardner haze-gard PLUS to have an average optical transmission (visible) = 93.1 ± 0.1% and Haze = 0.78 ± 0.08. The adhesion of the deposited coating was characterized with tape peel testing, with the results in Table 4: below. The adhesion results with the addition of Preparative Example 11 demonstrate substantial adhesion improvement compared with Comparative Examples 1 and 2, and furthermore there was no significant difference in the haze or refractive index of the deposited layer.

TABLE 4

Tape Peel Adhesion Test and Haze Results for the Examples (Tape peel results are given for the as-deposited coatings and after the heat aging time indicated; Haze results are given for as-deposited coatings)

| | | | FILM AS DEPOSITED | | | HEAT AGING (50° C., 24 HRS) | | | HEAT AGING (50° C., EXTENDED) | | | | |
|---|---|---|---|---|---|---|---|---|---|---|---|---|---|
| Sample ID | Coupling Agent (Lot ID) | Concentration n¹ (effective | POST-IT | X-HATCH 600 | X-HATCH 610 | POST-IT | X-HATCH 600 | X-HATCH 610 | POST-IT | X-HATCH 600 | X-HATCH 610 | AVG Haze | COMMENT S |
| Control | SiAlₓO_{y} -coated PET | N/A | | | | | | | | | | 1.3 0 | |
| Comparat ive Example 1 | NONE | N/A | | 100 % | 100 % | | | | | 100 % | 100 % | 1.2 2 | 1 |
| Comparative Example 2 | K90 | 5% | N | 95% | 79% | N | 68% | 52% | N | 72% | 91% | 2.5 2 | unstable, hazy |
| Example 1 | Preparative Example 1 | 90% | N | 40% | 68% | N | 0% | 9% | | | | 1.3 4 | |
| Example 2 | Preparative Example 2 | 5.5% | | 43% | | | | | | 0% | | | 2 |
| Example 6 | Preparative Example 2 | 90% | N | 0% | 23% | N | 0% | 27% | | | | 0.7 9 | |
| Example 3 | Preparative Example 3 | 5% | N | 96% | 55% | N | | | N | 51% | 29% | 1.3 2 | 3 |
| Example 7 | Preparative Example 2-3 | 46% | | 0% | 0% | | | | | | | | |
| Example 4 | Preparative Example 4 | 10% | N | 0% | 0% | N | 0% | 0% | | | | 1.5 2 | |
| Example 5 | Preparative Example 1-6 | 45% | N | 0% | 0% | N | 0% | 0% | | | | 0.7 5 | |
| Example 8 | Preparative Exampl e9 | 5% | N | 97% | 100 % | N | 92% | 100 % | | | | 0.7 8 | |
| Example 9 | Preparative Example 12 | 45% | | 0% | 33% | | | | | | | | |
| Example 10 | Preparative Example 10 | 45% | N | 0% | 0% | N | 0% | 16% | | | | 1.0 4 | |
| Example 11 | Preparative Example 11 | 45% | N | 0% | 0% | N | 0% | 0% | | | | 0.7 8 | |

¹ Extended aging time of 75 HRS
² Extended aging time of 150 HRS
³ Extended aging time of 1 WK

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.”

Furthermore, all publications and patents referenced herein are incorporated by reference in their entirety to the same extent as if each individual publication or patent was specifically and individually indicated to be incorporated by reference. Various exemplary embodiments have been described. These and other embodiments are within the scope of the following claims.

1. A multilayer optical film comprising:
a substrate;
at least a first optical layer overlaying a surface of the substrate, wherein the first layer comprises a (co)polymer obtained by polymerizing a polymerizable composition comprised of:
at least one free-radically polymerizable monomer, oligomer, or mixture thereof, and
at least one fluorinated coupling agent having one of the following formulas: 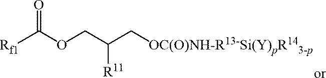 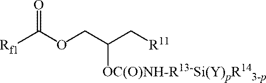
wherein:
R_{f1} is a monovalent perfluorooxyalkyl;
R¹³ is a divalent alkylene group, said alkylene groups optionally containing one or more catenary oxygen atoms;
R¹¹ is —[OC(O)—NH—R¹³]ₘ₁OC(O)CR¹⁵═CH₂ or —OC(O)—NH—R¹⁶(—OC(O)CR¹⁵═CH₂)₂;
Y is a hydrolysable group;
R¹⁴ is a monovalent alkyl or aryl group;
p is 1, 2, or 3;
R¹⁵ is H or CH₃;
R¹⁶ is a polyvalent alkylene group, said polyvalent alkylene group optionally containing one or more catenary oxygen atoms; and
m1 is 1 or 0; or 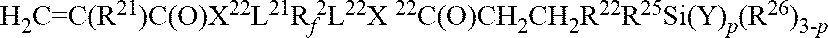
wherein:
R²¹ is H or CH₃;
X²² is -O-,-S-, or -NR²³- wherein R²³ is H or an alkyl group of 1 to 4 carbon atoms,
L²¹ and L²² are organic linking groups;
R_{f}² is a divalent perfluorooxyalkylene;
R²² is -S- or -N(R²⁴)- wherein R²⁴ is C₁-C₄ alkyl or -R²⁵Si(Y)₃;
R²⁵ is a divalent alkylene group optionally comprising one or more catenary oxygen atoms;
Y is a hydrolysable group;
R²⁶ is a non-hydrolysable group; and
p is 1, 2, or 3; or 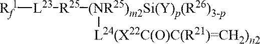
wherein:
R_{f}¹ is a monovalent perfluorooxyalkyl;
L²³ and L²⁴ are organic linking groups;
R²⁵ is a divalent alkylene group said alkylene groups optionally containing one or more catenary oxygen atoms;
Y is a hydrolysable group;
R²⁶ is a non-hydrolysable group;
p is 1, 2, or 3;
X²² is -O-, -S-, or -NR²³-, wherein R²³ is H or an alkyl group of 1 to 4 carbon atoms;
R²¹ is H or CH₃;
m2 is 1 or 2; and
n2 is 1, 2, or 3,
optionally wherein the polymerizable composition is comprised of the fluorinated coupling agent in an amount of at least 0.1, 0.5, 1.0, 1.5, 2.0, 2.5, 3.0, 3.5, or 4.0 wt. % based on the weight of the polymerizable composition.

2. The multilayer optical film of claim 1, further comprising at least one fluorinated initiator having one of the following formulas: 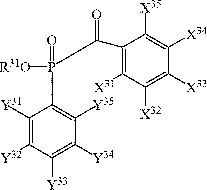
wherein:
X³¹, X³², X³³, X³⁴, X³⁵ are each independently selected from -H, -F, or -CF₃, with the proviso that at least 3 of X³¹, X³², X³³, X³⁴, X³⁵ are -F, or that at least 1 of X³¹, X³², X³³, X³⁴, X³⁵ is -CF₃;
Y³¹, Y³², Y³³, Y³⁴, Y³⁵ are each independently selected from -H, or CH₃; and
R³¹ is an alkyl group of 1 to 4 carbon atoms; or 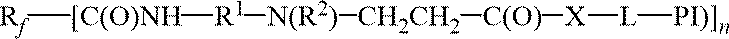
wherein:
R_{f} is a monovalent perfluorooxyalkyl group or divalent perfluorooxyalkylene group;
R¹ is an alkylene group optionally containing one or more catenary oxygen or nitrogen atoms,
R² is H or an alkyl group of 1 to 4 carbon atoms,
X is -O-, -S-, or -NR³-, wherein R³ is H or an alkyl group of 1 to 4 carbon atoms,
L is a covalent bond or divalent organic linking group;
PI is a photoinitiator group;
n is 1 when R_{f} is a monovalent perfluorooxyalkyl group or n is 2 when R_{f} is a divalent perfluorooxyalkylene group,
optionally wherein the polymerizable composition is comprised of the fluorinated coupling agent in an amount of at least 0.1, 0.5, 1.0, 1.5, 2.0, 2.5, 3.0, 3.5, or 4.0 wt. % based on the weight of the polymerizable composition.

3. The multilayer optical film of claim 1, wherein the free-radically polymerizable monomer, oligomer, or combination thereof is fluorinated.

4. The multilayer optical film of claim 1, wherein the free-radically polymerizable monomer, oligomer, or combination thereof has a fluorine content of at least 25, 30 or 35 wt.%.

5. The multilayer optical film of claim 1, wherein the polymerizable composition comprises a fluorinated oligomer including a perfluorooxyalkylene group.

6. (canceled)

7. The multilayer optical film of claim 1, wherein the polymerizable fluorinated coupling agent has a calculated number average molecular weight of no greater than 3000, 2500, 2000, 1500, 1000, or 500 g/mole.

8. The multilayer optical film of claim 1, wherein the fluorinated coupling agent has a fluorine content of at least 20, 25, 30, 35, 40, or 50 wt.%.

9. The multilayer optical film of claim 1, wherein the polymerizable composition is comprised of fluorinated coupling agent in an amount of no more than about 50, 40, 30, 20 or 10 wt. % based on the weight of the polymerizable composition.

10. The multilayer optical film of claim 1, further comprising at least one of a (meth)acrylic monomer or oligomer, optionally wherein the at least one (meth)acrylic monomer or oligomer comprises HFPO oligomer diacrylate of the structure CH₂═CHC(O)O—H₂C—(CF₃)CF—[OCF₂(CF₃)CF]ₛ—O(CF₂)ᵤO—[CF(CF₃)CF₂O]ₜ—CF(CF₃)—CH₂—OC(O)CH═CH₂, wherein u is from 2 to 6 and s and t are independently integers of 2 to 25.

11. The multilayer optical film of claim 1, further comprising at least one additional optical layer adjoining the at least first optical layer.

12. The multilayer optical film of claim 1, further comprising a plurality of alternating optical layers comprised of:
an optical layer overlaying the substrate and comprising an inorganic oxide, nitride, oxynitride, oxycarbide; a metal or metal alloy; a (co)polymer, or a combination thereof; and
an adjoining (co)polymer optical layer overlaying the substrate and comprising a (co)polymer.

13. The multilayer optical film of claim 1, wherein the substrate comprises a flexible transparent polymeric film, optionally wherein the substrate comprises polyethylene terephthalate (PET), polyethylene terephthalate glycol (PETg), polyethylene napthalate (PEN), heat stabilized PET, heat stabilized PEN, polyoxymethylene, polyvinylnaphthalene, polyetheretherketone, a fluoropolymer, polycarbonate, polymethylmeth(meth)acrylate, poly α-methyl styrene, polysulfone, polyphenylene oxide, polyetherimide, polyethersulfone, polyamideimide, polyimide, polyphthalamide, cyclic olefin polymer (COP), cyclic olefin copolymer (COC), triacetate cellulose (TAC), or combinations thereof.

14. (canceled)

15. (canceled)

16. The multilayer optical film of claim 14, wherein the at least first optical layer has a refractive index of less than 1.4, optionally wherein the refractive index of the first optical layer is from 1.3 to 1.4.

17. The multilayer optical film of claim 15, wherein the at least second optical layer adjoining the at least first optical layer has a refractive index of at least 1.4, optionally wherein the refractive index of the at least second optical layer is from 1.4 to 1.5, 1.6 to 1.7, 1.7 to 1.8, at least 2.0, at least 2.2, or at least 2.4.

18. The multilayer optical film of claim 11, wherein at least one of the substrate, the at least first optical layer, the at least second optical layer, or a combination thereof, further comprises a plurality of nanostructures or microstructures.

19-21. (canceled)

22. An article incorporating the multilayer optical film according to claim 1, wherein the article is selected from a photovoltaic device, a display device, a solid-state lighting device, a sensor, a medical or biological diagnostic device, or a combination thereof.

23. A process for making a multilayer optical film according to claim 1, comprising:
forming at least one (co)polymer layer overlaying a major surface of a substrate,
wherein the (co)polymer layer is the reaction product of the polymerizable composition of claim 1, optionally wherein the polymerizable composition is comprised of the fluorinated coupling agent in an amount of at least 0.1, 0.5, 1.0, 1.5, 2.0, 2.5, 3.0, 3.5, or 4.0 wt. % based on the weight of the polymerizable composition; and
applying at least one optical layer overlaying the major surface of the substrate.

24. The process of claim 23, wherein forming the at least one (co)polymer layer further comprises:
evaporating the polymerizable composition;
condensing the evaporated polymerizable composition as a layer overlaying the substrate; and
reacting the polymerizable composition in the layer to form the (co)polymer, optionally wherein the method is carried out using a roll of the substrate in a substantially continuous roll-to-roll process.

25. The process of claim 23, wherein applying the at least one optical layer comprises depositing at least one of a metal oxide, metal oxide precursor, (meth)acrylic (co)polymer, meth(acrylic (co)polymer precursor, or a combination thereof, onto the substrate to form the optical layer, wherein depositing is achieved using sputter deposition, reactive sputtering, thermal evaporation, electron-beam evaporation, chemical vapor deposition, plasma-assisted chemical vapor deposition, atomic layer deposition, plasma-assisted atomic layer deposition, organic vapor deposition, or a combination thereof.

26. (canceled)

27. The process of claim 24, wherein evaporating the polymerizable composition further comprises at least one of co-evaporating the fluorinated coupling agent and the at least one free-radically polymerizable monomer, oligomer, or mixture thereof from a liquid mixture, or sequentially evaporating the fluorinated coupling agent and the at least one free-radically polymerizable monomer, oligomer, or mixture thereof
from separate liquid sources, or sequentially evaporating the fluorinated coupling agent and the at least one free-radically polymerizable monomer, oligomer, or mixture thereof
from separate liquid sources, optionally wherein the polymerizable composition is comprised of the fluorinated coupling agent in an amount of no more than about 50, 40, 30, 20 or 10 wt. % based on the weight of the polymerizable composition.

28-31. (canceled)
